(19) United States
(12) Patent Application Publication
(10) Pub. No.: US 2022/0336687 A1
(43) Pub. Date: Oct. 20, 2022

(54) DOPING AND PASSIVATION FOR HIGH EFFICIENCY SOLAR CELLS

(71) Applicant: Colorado State University Research Foundation, Fort Collins, CO (US)

(72) Inventors: Walajabad S. Sampath, Fort Collins, CO (US); Amit H. Munshi, Fort Collins, CO (US); Ramesh Pandey, Fort Collins, CO (US); Akash Shah, Fort Collins, CO (US); Tushar Shimpi, Windsor, CO (US)

(73) Assignee: Colorado State University Research Foundation, Fort Collins, CO (US)

(21) Appl. No.: 17/837,755

(22) Filed: Jun. 10, 2022

Related U.S. Application Data
(63) Continuation-in-part of application No. 16/404,479, filed on May 6, 2019.
(60) Provisional application No. 62/668,006, filed on May 7, 2018.
(60) Provisional application No. 62/668,014, filed on May 7, 2018.
(60) Provisional application No. 63/209,250, filed on Jun. 10, 2021.
(60) Provisional application No. 63/311,978, filed on Feb. 19, 2022.

(51) Int. Cl. H01L 31/0296; H01L 31/18; H01L 31/0216

(52) U.S. Cl. CPC H01L 31/02966; H01L 31/1832; H01L 31/02167; H01L 31/1868

(57) ABSTRACT

The present disclosure relates to thin-film solar cells with improved efficiency and methods for producing thin-film solar cells having increased efficiency. In certain embodiments, thin-film solar cells having an efficiency of over 21%, over 20%, over 19%, over 15%, over 10%, etc. has been obtained using the methods of the disclosure. In certain aspects, the methods of the disclosure use passivation, passivating oxides, and/or doping treatments in increase the efficiency of the thin-film solar cells; e.g., CdTe-based thin-film solar cells.

### CROSS-REFERENCE TO RELATED APPLICATIONS

The present application is a continuation-in-part application of U.S. application Ser. No. 16/404,479, filed May 6, 2019, which claims the benefit of the filing date under 35 U.S.C. § 119(e) of U.S. Application No. 62/668,006, filed May 7, 2018 and U.S. Application No. 62/668,014, filed May 7, 2018. The present application also claims the benefit of U.S. Provisional Application No. 63/209,250, filed Jun. 10, 2021 and U.S. Provisional Application No. 63/311,978, filed Feb. 19, 2022. The contents of each of which are herein incorporated by reference in their entireties.

### STATEMENT OF GOVERNMENT SUPPORT

The present invention was made with government support under grants DE-EE0008177, DE-EE0008557, and DE-EE0008974 awarded by the United States Department of Energy. The government has certain rights in the present disclosure.

### FIELD OF THE DISCLOSURE

The present disclosure relates generally to thin-film solar cells. In particular, the present disclosure relates to a method increasing efficiency of a semiconducting/absorber layer.

### BACKGROUND OF THE DISCLOSURE

Sustainable energy resources have presented many opportunities and challenges in modern society. One source of sustainable energy can be found in solar cells. Solar cells are an electrical device that can be used to convert light energy into electricity. Solar cells can be used to produce electrical characteristics, such as current, voltage, and resistance, in varying ranges when exposed to light based on the components within the cell. Thin-film solar cells are a second generation form of the solar cell which can be made by depositing one or more thin layers on a substrate. Thin-film solar cells can significantly reduce the cost of energy when compared to coal, nuclear, gas, and diesel energy sources. Thin-film semi-conductor technology is currently being used world-wide and has been commercialized at the gigawatts (GW)-per-year scale, with nearly 17.5 GWs installed globally. However, while thin-film solar cells require only a fraction of the semiconductor materials required by their predecessors, the thin-film solar cells tend to be less efficient than the conventional, first-generation solar cells.

Solar cells can be made of thin-film semi-conductor materials. Various improvements have been made to thin-film solar cells over the past several decades. Specifically efficiency of thin-film solar cells has increased from about 16% to about 18% in just two years from 2014 to 2016. Commercially available solar cells generate energy at about 18% efficiency with about 28 mA/cm² short-circuit current and 850 mV open-circuit voltage. CdTe-based PV technology has one of the lowest costs for manufacturing and energy generation not only among all renewable energy sources, but also conventional energy sources. Although this technology has demonstrated very low cost of manufacturing, further reduction in the cost of module manufacturing is desired for capturing greater share of energy market. CdTe being a direct bandgap material, can produce reasonable efficiency even under diffused light conditions. In other words, CdTe solar panels can produce appreciable amounts of energy even under moderate cloud cover as well as at sunrise and sunset when the light is not directly incident on the panel.

### SUMMARY OF THE DISCLOSURE

One aspect of the disclosure is directed to a thin-film solar cell with improved efficiency, the thin-film solar cell comprising: a semiconducting/absorber layer; at least one p+ layer; and one or more oxide layers passivated onto at least one surface of the semiconducting/absorber layer. In certain embodiments, the thin-film solar cell exhibits an efficiency of at least 10%.

In another aspect of the disclosure, thin-film solar cells with improved efficiency are provided wherein at least one of the oxide layers is passivated onto the front-surface of the semiconducting/absorber layer.

In certain embodiments, the at least one oxide layer on the front-surface of the semiconducting/absorber layer is formed from aluminum oxide (Al₂O₃). In certain embodiments, the at least one oxide layer on the front-surface of the semiconducting/absorber layer is about 2 nanometers (nm) to 10 nm in thickness.

In another aspect of the disclosure, thin-film solar cells with improved efficiency are provided which comprise at least one additional oxide layer in addition to the at least one oxide layer on the front-surface of the semiconducting/absorber layer. In certain embodiments, the at least one additional oxide layer is passivated onto the back-surface of the semiconducting/absorber layer.

In certain embodiments, the at least one oxide layer on the back-surface of the semiconducting/absorber layer is aluminum oxide (Al₂O₃). In certain embodiments, the at least one oxide layer on the back-surface of the semiconducting/absorber layer is about 2 nm to 100 nm in thickness.

In certain embodiments, the semiconducting/absorber layer may be formed from a material comprising cadmium telluride (CdTe) and/or a ternary alloy of CdTe comprising CdSeTe, CdMgTe, CdZnTe or CdHgTe.

In other embodiments, the at least one oxide layer may be formed from a material selected from the group consisting of copper aluminum oxide (CuAlO₃), strontium copper oxide (SrCu₂O₂), copper oxide (Cu₂O), magnesium zinc oxide (MgZnO), aluminum oxide (Al₂O₃), and tin oxide (SnO₂).

In yet other embodiments, prior to passivating the at least one oxide layer onto at least one surface of the semiconducting/absorber layer, the at least one surface of the semiconducting/absorber layer is doped using a dopant selected from the group consisting of nitrogen, phosphorus, arsenic, antimony, and bismuth, and copper. In certain embodiments, the semiconducting/absorber layer is doped with copper. In other embodiments, the semiconducting/absorber layer is doped with arsenic. In even further embodiments, the semiconducting/absorber layer is not doped. By way of example, the semiconducting/absorber layer may be doped to produce both a front-surface contact and a back-surface contact.

In yet other embodiments, thin-film solar cells with improved efficiency may further comprising a telluride layer disposed beneath the semiconducting/absorber layer.

In yet other embodiments, thin-film solar cells with improved efficiency may comprise a plurality of oxide layers. In certain embodiments, at least one of the plurality of oxide layers are formed from magnesium zinc oxide (MgZnO). In other embodiments, the plurality of oxide layers produce a high-band gap cell, a mid band-gap cell, and a low-band gap cell.

Other aspects of the disclosure are directed to a thin-film solar cell with improved efficiency, the thin-film solar cell comprising: a semiconducting/absorber layer comprising a front-surface and a back-surface; one or more oxide layers passivated onto the front-surface of the semiconducting/absorber layer; and one or more oxide layers passivated onto the back-surface of the semiconducting/absorber layer. In certain embodiments, the thin-film solar cell exhibits an efficiency of at least 10%.

In certain embodiments, a first layer of the one or more oxide layers on the front-surface of the semiconducting/absorber layer is formed from silicon dioxide (SiO₂), magnesium oxide (MgO), or magnesium zinc oxide (MgZnO). In some embodiments, the first layer on the front-surface of the semiconducting/absorber layer is less than 100 nm in thickness, about 2 nm to 5 nm in thickness, or less than 2 nm in thickness.

In some embodiments, the thin-film solar cell comprises at least one additional oxide layer on the front-surface of the semiconducting/absorber layer. The at least one additional oxide layer on the front-surface may be formed from a material selected from the group consisting of copper aluminum oxide (CuAlO₃), strontium copper oxide (SrCu₂O₂), copper oxide (Cu₂O), MgZnO, aluminum oxide (Al₂O₃), and tin oxide (SnO₂).

In certain embodiments, a first layer of the at least one oxide layers on the back-surface of the semiconducting/absorber layer is formed from a material selected from the group consisting of MgO, Al₂O₃, and tellurium dioxide (TeO₂). In some embodiments, 9 the first layer on the back-surface of the semiconducting/absorber layer is less than 100 nm in thickness, about 2 nm to 5 nm in thickness, or less than 2 nm in thickness.

In other embodiments, the thin-film solar cell comprises at least one additional oxide layer on the back-surface of the semiconducting/absorber layer. The at least one additional oxide layer on the back-surface may be formed from a material selected from the group consisting of nickel oxide (NiO), copper aluminum oxide (CuAlO₃), strontium copper oxide (SrCu₂O₂), copper oxide (Cu₂O), magnesium zinc oxide (MgZnO), aluminum oxide (Al₂O₃), ZnO:Al, and tin oxide (SnO₂). In at least one example, the at least one additional oxide layer on the back-surface is formed from NiO doped with copper.

In certain embodiments, the semiconducting/absorber layer is formed from a material comprising cadmium telluride (CdTe) and/or a ternary alloy of CdTe comprising CdSeTe, CdMgTe, CdZnTe or CdHgTe. In some embodiments, prior to passivating the at least one oxide layer onto at least one back-surface of the semiconducting/absorber layer, the at least one surface of the semiconducting/absorber layer is doped using a dopant selected from the group consisting of nitrogen, phosphorus, arsenic, antimony, and bismuth, and copper. For example, the semiconducting/absorber layer may be doped with arsenic. In other embodiments, the semiconducting/absorber layer is not doped and further comprises a transparent contact deposited on the one or more oxide layers passivated onto the back-surface of the semiconducting/absorber layer.

In certain embodiments, the thin-film solar cell further comprises a telluride layer disposed on one or more oxide layers on the back-surface the semiconducting/absorber layer.

Other aspects of the present disclosure include a method for producing a thin-film solar cell with improved efficiency. In certain embodiments, the method comprises: providing a semiconducting/absorber layer; depositing one or more one oxide layers onto a front-surface of the semiconducting/absorber layer; depositing one or more one oxide layers onto a back-surface of the semiconducting/absorber layer; and passivating the deposited one or more oxide layers. In some embodiments, the one or more oxide layers on both the front-surface and the back-surface of the semiconducting/absorber layer are less than 100 nm in thickness, and the thin-film solar cell has an efficiency of at least 10%.

In certain embodiments, the method further comprises doping the semiconducting bulk material with a dopant. In some embodiments, the semiconducting bulk material is doped after depositing and passivating the one or more oxide layers.

In some embodiments, a first layer of the one or more oxide layers on the front-surface of the semiconducting/absorber layer is formed from silicon dioxide (SiO₂), magnesium oxide (MgO), or magnesium zinc oxide (MgZnO). The first layer on the front-surface of the semiconducting/absorber layer may be about 2 nm to 5 nm in thickness or less than 2 nm in thickness.

In other embodiments, the method further comprises depositing at least one additional oxide layer on the front-surface of the semiconducting/absorber layer. The at least one additional oxide layer on the front-surface may be formed from a material selected from the group consisting of copper aluminum oxide (CuAlO₃), strontium copper oxide (SrCu₂O₂), copper oxide (Cu₂O), MgZnO, aluminum oxide (Al₂O₃), and tin oxide (SnO₂).

In certain embodiments, a first layer of the at least one oxide layers on the back-surface of the semiconducting/absorber layer is formed from a material selected from the group consisting of MgO, Al₂O₃, and tellurium dioxide (TeO₂). The first layer on the back-surface of the semiconducting/absorber layer may be about 2 nm to 5 nm in thickness or less than 2 nm in thickness.

In some embodiments, the method further comprises depositing at least one additional oxide layer on the back-surface of the semiconducting/absorber layer. The at least one additional oxide layer on the back-surface may be formed from a material selected from the group consisting of nickel oxide (NiO), copper aluminum oxide (CuAlO₃), strontium copper oxide (SrCu₂O₂), copper oxide (Cu₂O), magnesium zinc oxide (MgZnO), aluminum oxide (Al₂O₃), ZnO:Al, and tin oxide (SnO₂). In at least one example, the at least one additional oxide layer on the back-surface is formed from NiO doped with copper.

In certain embodiments, the semiconducting/absorber layer is formed from a material comprising cadmium telluride (CdTe) and/or a ternary alloy of CdTe comprising CdSeTe, CdMgTe, CdZnTe or CdHgTe. In some embodiments, the method further comprises doping the at least one surface of the semiconducting/absorber layer with a dopant prior to passivating the at least one oxide layer onto at least one back-surface of the semiconducting/absorber layer. The dopant may be selected from the group consisting of nitrogen, phosphorus, arsenic, antimony, and bismuth, and copper. For example, the semiconducting/absorber layer may be doped with arsenic. In other embodiments, the semiconducting/absorber layer is not doped and further comprises a transparent contact deposited on the one or more oxide layers passivated onto the back-surface of the semiconducting/absorber layer.

In some embodiments, the method further comprises depositing a telluride layer on one or more oxide layers on the back-surface the semiconducting/absorber layer.

Other aspects of the disclosure are directed to a method for producing a thin-film solar cell with improved efficiency as described herein, the method comprising: providing an semiconducting bulk material; depositing one or more one oxide layers onto at least one surface of the semiconducting bulk material; passivating the deposited one or more oxide layer; and doping the semiconducting bulk material with a dopant to thereby form a semiconducting/absorber layer. In certain embodiments, the doping of the semiconducting bulk material after depositing and passivating the one or more oxide layers produces a thin-film solar cell with an efficiency of at least 10% or at least 20%. In certain embodiments, at least one of the oxide layers is passivated onto the front-surface of the semiconducting material.

These and other aspects and iterations of the disclosure are described in more detail below.

### BRIEF DESCRIPTION OF THE DRAWINGS

Implementations of the present technology will now be described, by way of example only, with reference to the attached figures, wherein:

FIGS. 1A and 1B illustrate graphs of photoluminescence intensity;

FIG. 2 is a graph illustrating open-circuit voltage, short-circuit current density, fill-factor and efficiency within a treated solar cell;

FIG. 3A illustrates an exemplary single-junction solar cell in accordance with the present disclosure;

FIG. 3B illustrates an exemplary multi junction solar cell in accordance with the present disclosure;

FIG. 4 is a schematic diagram indicating device efficiency improvements;

FIG. 5 is an enlarged view of the 2017 CdTe device and corresponding performance chart;

FIG. 6 illustrates an exemplary solar cell in accordance with the present disclosure;

FIG. 7A illustrates an exemplary solar cell used for testing the optimization of Cd overpressure for As doping;

FIG. 7B, FIG. 7C, FIG. 7D, FIG. 7E, FIG. 7F, FIG. 7G, FIG. 7H, and FIG. 7I show the results of As doping with and without heat and Cd vapor overpressure on open-circuit voltage, short-circuit voltage, fill-factor, and efficiency on the exemplary solar cell shown in FIG. 7A. BL—baseline absorber, CS—Co-sublimation source, OP—Cd vapor overpressure;

FIG. 8A illustrates an exemplary solar cell used for testing the effect of CdCl₂ treatment time with a gallium doped magnesium zinc oxide buffer layer;

FIG. 8B, FIG. 8C, FIG. 8D, and FIG. 8E show the results of the effect of CdCl₂ treatment time on open-circuit voltage, short-circuit voltage, fill-factor, and efficiency on the exemplary solar cell shown in FIG. 8A. CdCl₂ treatment time is in seconds, performed at 460° C.;

FIG. 9A, FIG. 9B, and FIG. 9C are DFT simulations showing effect of higher doping at the back of the absorber;

FIG. 10A illustrates an exemplary solar cell used for testing the improvement of CdTe:As devices with NiO contacts;

FIG. 10B, FIG. 10C, FIG. 10D, FIG. 10E, and FIG. 10F show the results of different NiO layer thickness on open-circuit voltage, short-circuit voltage, fill-factor, efficiency, and current density on the exemplary solar cell shown in FIG. 10A;

FIG. 11A illustrates an exemplary solar cell used for testing doping with arsenic and copper treatment;

FIG. 11B, FIG. 11C, FIG. 11D, and FIG. 11E show the results of doping with arsenic and copper on open-circuit voltage, short-circuit voltage, fill-factor, efficiency, and current density on the exemplary solar cell shown in FIG. 11A;

FIG. 12A illustrates an exemplary solar cell used for testing arsenic doping with NiO/NiO:Cu and the effect on MZO thickness;

FIG. 12B, FIG. 12C, FIG. 12D, FIG. 12E, show the results of As doping with NiO/NiO:Cu and MZO thickness on open-circuit voltage, short-circuit voltage, fill-factor, and efficiency on the exemplary solar cell shown in FIG. 12A

FIG. 12F, FIG. 12G, FIG. 1211, and FIG. 121 show the results of the stability of arsenic with NiO:Cu over time on voltage, current density, fill-factor, and efficiency on the exemplary solar cell shown in FIG. 12A

FIG. 13A illustrates an exemplary solar cell used for testing SiO₂ with MZO for better front interface passivation;

FIG. 13B, FIG. 13C, FIG. 13D, and FIG. 13E show the results of SiO₂ with MZO on open-circuit voltage, short-circuit voltage, fill-factor, and efficiency on the exemplary solar cell shown in FIG. 13A;

FIG. 13F shows the results of the effect of SiO2 thickness on J-V performance on the exemplary solar cell shown in FIG. 13A;

FIG. 14A illustrates an exemplary solar cell used for testing MgO for back surface passivation;

FIG. 14B, FIG. 14C, FIG. 14D, FIG. 14E, FIG. 14F, and FIG. 14G show the results of using MgO for back surface passivation on open-circuit voltage, short-circuit voltage, fill-factor, efficiency, PL counts, and current density on the exemplary solar cell shown in FIG. 14A;

FIG. 15A illustrates a schematic diagram of an exemplary solar cell device;

FIG. 15B, FIG. 15C, and FIG. 15D, show the results of adding various layers on the open-circuit voltage, short-circuit voltage, fill-factor, efficiency, and current density on the exemplary solar cell shown in FIG. 15A;

FIG. 16A illustrates a schematic diagram of an exemplary solar cell device showing MZO being replaced by MgO at the front interface;

FIG. 16B illustrates a schematic diagram of an exemplary solar cell device showing MgO on the back surface;

FIG. 17 shows PL measurements done on devices with illumination from both front and back using a 520 nm excitation laser. Inset represents the zoomed region of PL signal from the back illumination;

FIG. 18A, FIG. 18B, and FIG. 18C show current density-voltage and external quantum efficiency characterization of fabricated devices showing good bifacial behavior.

### DETAILED DESCRIPTION

Disclosed herein is a method for producing thin-film solar cells having increased efficiency, and thin film solar cells produced by such methods. In certain aspects, the methods of the disclosure use passivation, passivating oxides, and/or doping treatments in increase the efficiency of the thin-film solar cells; e.g., CdTe-based thin-film solar cells. In certain embodiments, thin-film solar cells having an efficiency of over 22%, over 21%, over 20%, over 19%, over 15%, over 10%, etc. has been obtained using the methods of the disclosure.

As described in more detail herein, in certain aspects, the disclosure provides a thin-film solar cell with improved efficiency. In certain embodiments, the thin-film solar cell includes: a semiconducting/absorber layer; at least one p+ layer; and at least one oxide layer passivated onto at least one surface of the semiconducting layer. In some embodiments the thin-film solar cell includes: a semiconducting/absorber layer; at least one oxide layer passivated onto both surfaces of the semiconducting layer; and at least one carrier selective layer contacting each oxide layer. In certain embodiments, the thin-film solar cell exhibits an efficiency of at least 10%, at least 11%, at least 12%, at least 13%, at least 14%, at least 15%, at least 16%, at least 17%, at least 18%, at least 19%, at least 20%, at least 22%, etc. In some embodiments, the thin-film solar cell exhibits single junction efficiencies close to the Shockley-Queisser limit.

In certain aspects of the disclosure, it has been found that use of an oxide such as Al₂O₃, MgO, or SiO₂ provides beneficial performance, stability, and manufacturability as compared to more traditional oxides such as MgZnO, particularly when used at the front-interface of the semiconducting layer. As such, in certain embodiments of the disclosure, the thin-film solar cell includes one or more oxide layers passivated onto at least one surface of the semiconducting layer, wherein at least one of the oxide layers is passivated onto the front-surface of the semiconducting/absorber layer. In other embodiments, the thin-film solar cell includes at least one oxide layer passivated onto the front-surface of the semiconducting/absorber layer and at least one oxide layer passivated onto the back-surface of the semiconducting/absorber layer. In some examples, the at least one oxide layer on the front-surface of the semiconducting/absorber layer is formed from aluminum oxide (Al₂O₃) or silicon dioxide (SiO₂). In other examples, the at least one oxide layer on the back-surface of the semiconducting/absorber layer is formed from Al₂O₃, magnesium oxide (MgO), tellurium dioxide (TeO₂), or other suitable films.

In certain embodiments, the semiconducting/absorber layer may be formed from a material comprising cadmium telluride (CdTe), copper indium gallium diselenide (CIGS), or amorphous thin-film silicon (a-Si, TF-Si). By way of non-limiting example, the semiconducting/absorber layer may be formed from a material comprising cadmium telluride (CdTe), and/or a ternary alloy of CdTe, such as CdSeTe, CdMgTe, CdZnTe or CdHgTe. In some embodiments, deposition of a TeO₂ layer followed by a Te deposition at the back surface of CdTe-based PV may have the same effect as doping. In an embodiment, using a NiO:Cu layer may further improve such device performance.

In certain embodiments, one or more oxide layers may be formed from a material comprising copper aluminum oxide (CuAlO₃), strontium copper oxide (SrCu₂O₂), copper oxide (Cu₂O), magnesium zinc oxide (MgZnO or MZO), aluminum oxide (Al₂O₃), tin oxide (SnO₂), magnesium oxide (MgO), silicon dioxide (SiO₂), tellurium dioxide (TeO₂), etc. In certain aspects, prior to passivating the oxide layer onto at least one surface of the semiconducting layer, the semiconducting layer may be doped. In other aspects, the semiconducting layer may be doped after depositing and passivating the oxide layer onto at least one surface of the semiconducting layer. In various examples, the dopant may be selected from, e.g., nitrogen, phosphorus, arsenic, antimony, bismuth, copper, etc.

In certain aspects, the at least one surface of the semiconducting/absorber layer is a front-surface or a back-surface. In certain aspects, an oxide layer can be passivated on to the front-surface only, the back-surface only, or both the front-surface and the back-surface of the semiconducting/absorber layer. In certain aspects, the oxide layer passivated onto the front and back-surfaces of the semiconducting/absorber material can be the same oxide. In other aspects, the oxide layer passivated onto the front and back surfaces of the semiconducting/absorber material can be different oxides. In certain aspects, one or more oxide layers on the front-surface, the back-surface, or both the front and the back-surfaces of the semiconducting/absorber layer can be from less than about 1 nanometer (nm) in thickness to about 200 nm in thickness, from about 2 nanometers (nm) in thickness to about 120 nm in thickness, from about 1 nm to about 2 nm in thickness, from about 1.5 nm to about 2.5 nm in thickness, from about 1 nm to about 3 nm in thickness, from about 2 nm to about 4 nm in thickness, from about 2 nm to about 5 nm in thickness, from about 2 nm to about 10 nm in thickness, less than 10 nm in thickness, less than 5 nm in thickness, less than 2 nm in thickness, etc. Without being limited to any one theory, the thickness of the oxide layers may improve the efficiency of the solar cell. If the oxide layer is too thick, then light may not be able to efficiently pass through the layer.

Other aspects of the disclosure provide a method for producing a thin-film solar cell with improved efficiency. In certain embodiments, the method includes providing an semiconducting bulk material; depositing at least one oxide layer onto at least one surface of the semiconducting material; passivating the deposited at least one oxide layer; and doping the semiconducting bulk material with a dopant to thereby form the semiconducting/absorber layer; wherein the doping of the semiconducting bulk material after depositing and passivating the at least one oxide layer thereby increases efficiency of the thin-film solar cell.

In additional aspects, the traditional opaque metal electrode at the back of the solar cell may be replaced with a transparent oxide combined with a transparent contacting film. In doing so, current similar to traditional contacts can be extracted, in addition to allowing light to be absorbed from the back of the panel. Such a device configuration may produce up to 20% more power than a solar cell with traditional metal electrodes.

As described in further detail herein, in accordance with embodiments of the methods of disclosure, thin-film solar cells may be produced by depositing one or more thin layers onto a semiconducting material. In general, all solar cells are considered photovoltaic, or as having the ability to convert light into electricity using semiconducting materials, regardless of whether the light source is natural or artificial. As used herein, the term “photovoltaic” refers to the production of electric current at the junction of two substances exposed to light. Typically, photovoltaic solar cells include a sheet of glass on the surface (or light-facing side) of the cell, allowing light to pass through but protecting the semiconductor material below. Different semiconducting materials used in photovoltaic cells can produce different results. Additionally, some solar cells can be made of only a single layer of light-absorbing material, also referred to as “single-junction”, or multiple layers of light-absorbing materials, also referred to as “multi-junction”. These layers of light-absorbing materials can be used to take advantage of various absorption and charge separation mechanisms. Typically, in thin-film solar cells, the semiconducting/absorber material is cadmium telluride (CdTe), copper indium gallium diselenide (CIGS), or amorphous thin-film silicon (a-Si, TF-Si). By way of non-limiting example, the semiconducting/absorber layer may be formed from a material comprising cadmium telluride (CdTe), and/or a ternary alloy of CdTe, such as CdSeTe, CdMgTe, CdZnTe or CdHgTe. In some embodiments, the CdTe layer may range from about 1 μm to 8 μm in thickness.

The several layers of various materials can be disposed on and around the semiconducting material; these materials can have a significant effect on the efficiency at which the solar cell produces energy. In at least one embodiment, materials can be disposed on all surfaces of the semiconducting material. In at least one example, oxide layers can be disposed on a front-surface and a back-surface of the semiconducting material. For example, oxide layers can be included in the solar cell device to act as a buffer layer and to assist in the transfer of electrons throughout the solar cell device. The method for producing the solar cell device as disclosed herein can include passivating an oxide layer on to the semiconducting/absorber layer. The term “passivate” as used herein means to coat a surface with an inert material in order to protect the surface from contamination. Oxides which can be used in the method disclosed herein can include, but are not limited to, copper aluminum oxide (CuAlO₃), strontium copper oxide (SrCu₂O₂), copper oxide (Cu₂O), magnesium zinc oxide (MgZnO), aluminum oxide (Al₂O₃), tin oxide (SnO₂), magnesium oxide (MgO), silicon dioxide (SiO₂), or any other suitable oxide. In one embodiment, a single oxide layer may be used to create a single junction cell as described herein. In an alternative embodiment, more than one oxide layer may be used to produce a multi junction solar cell, as described herein.

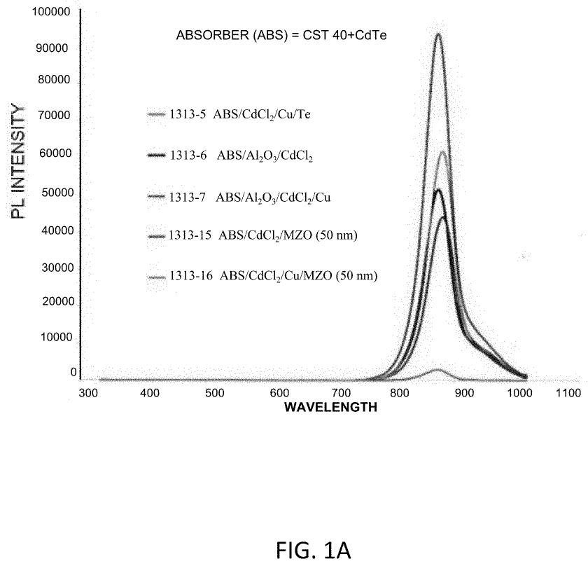

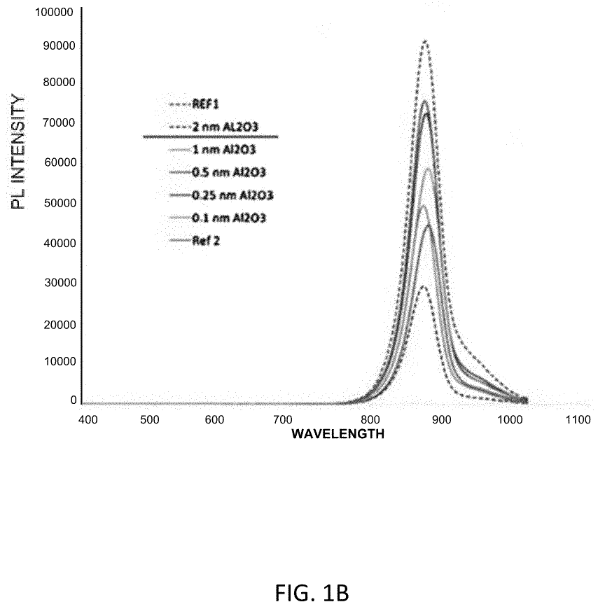

In exemplary embodiments of thin-film solar cells, the use of multiple oxide layers within a solar cell can increase the photoluminescence (PL) intensity of the resulting solar cell. The term “photoluminescence” as used herein refers to light emission from any form of matter after the absorption of photons (i.e., electromagnetic radiation). PL is used to evaluate the quality of device absorber and interface prior to depositing the back electrode. Typically, higher PL intensity indicates film quality and interface quality for higher efficiency devices. In creating a multi junction solar cell device, the properties of the final device can be determined by the thickness of each layer and order in which the oxide layers are disposed onto the substrate material. For example, the band alignment of the oxide layers can be a critical component in determining the efficiency of the resulting solar cell device, as shown in FIGS. 1A and 1B. The phrase “band alignment” or “band offset” as used herein refers to the relative alignment of the energy bands at semiconductor heterojunctions. The term “heterojunction” as described herein refers to an interface that occurs between two layers or regions of dissimilar crystalline semiconductors.

Solar cells having different materials and different oxide layers can produce different PL intensities. For example, oxide layer thickness can also be a factor, the number and thickness of each of the oxide layers can be adjusted in order to achieve desired results. For example, thin oxide layers can be used in order to allow the charge to tunnel through the thicker layers of the oxide film, or through naturally occurring voids in the film which can allow for charge conduction.

FIG. 1A illustrates a graph indicating the PL intensity at specific wavelengths for five exemplary solar cells, 1313-5, 1313-6, 1313-7, 1313-15, and 1313-16. Each of the solar cells having an absorber layer (indicated in the FIG. as “ABS”), such as CST40 and CdTe, as well as various other materials. For example, FIG. 1A illustrates that solar cells having different materials, such as oxide layers, produce final products having different PL intensities. As shown, solar cell 1313-7, comprising an absorber of CST 40+ CdTe, Al₂O₃, a passivation treatment of cadmium chloride (CdCl₂), and a Cu doping, produces the highest PL intensity.

Moreover, FIG. 1B is a graph illustrating how the PL intensities is affected by oxide layer thickness in the same solar cell. Specifically, FIG. 1B illustrates various embodiments of the 1313-7 solar cell described above, each of the embodiments having a different Al₂O₃ layer thickness. As shown, the embodiments displayed in FIG. 1B have oxide layer thicknesses ranging from 0.1 nanometers (nm) to 2 nm, as well as two reference cells (REF 1 and REF 2). As illustrated, the thickness of each of the oxide layers can be adjusted in order to produce a solar cell having different properties. While FIG. 1B indicates the highest PL intensity is achieved with the thickest oxide layer, it would be obvious to those having skill in the art that oxide layer thicknesses can be adjusted to produce beneficial results, and thinner layers may be more beneficial to certain embodiments based on the other components present in the solar cell device. For example, thin oxide layers can be used in order to allow the charge to tunnel through the thicker layers of the oxide film, or through naturally occurring voids in the film which can allow for charge conduction.

As described above, various oxides can be used in the creation of solar cell devices. Each oxide can provide specific properties to the final solar cell device. In selecting which oxides are the most beneficial to the solar cell device, one factor that must be considered is energy band alignment. For example, some oxides can provide more favorable band-alignments than others. Oxides which can produce more favorable band-alignment can be deposited on the semiconducting material in thin layers. For example, the oxide layers may be deposited in thicknesses ranging from about less than about 1 nm to about 200 nm, 2 nm to 120 nm, 2 nm to about 100 nm, about 10 nm to about 100 nm, about 20 nm to about 100 nm, about 1 nm to about 10 nm, about 1 nm to about 5 nm, about 1 nm to about 2 nm, less than about 5 nm, less than about 2 nm, etc. In certain embodiments, under 1 nm thickness may also be efficiently utilized.

In various embodiments, the solar cell may include one or more oxide layers passivated onto the front-surface of the semiconducting/absorber layer and one or more oxide layers passivated onto the back-surface of the semiconducting/absorber layer. In additional embodiments, the solar cell may include at least one additional oxide layer on the front-surface of the semiconducting/absorber layer and/or at least one additional oxide layer on the back-surface of the semiconducting/absorber layer. In at least one example, favorable oxides can include, but are not limited to, CuAlO₃, SrCu₂O₂, Cu₂O, MgO, SiO₂, MgZnO, Al₂O₃, SnO₂, TeO₂, ZnO:Al, and NiO:Cu. In an alternative example, oxides can be deposited on the semiconducting material in thin layers. For example, the oxide layers may be deposited in thicknesses ranging from less than about 1 nm to as high as about 200 nm, about 1 nm to 20 nm, about 1 nm to about 10 nm, about 1 nm to about 5 nm, about 1 nm to about 2 nm, less than about 5 nm, less than about 2 nm, etc. Again, in certain embodiments, under 1 nm thickness may be efficiently utilized. However, while the band alignment may be less favorable than other oxides, the thin oxide layers can still be used to achieve desired properties in the final solar cell device.

In at least one example, oxides which can provide beneficial properties to a solar cell device when deposited in thin layers can include, but are not limited to, MgZnO and Al₂O₃. See, e.g., Kephart, Jason M., Anna Kindvall, Desiree Williams, Darius Kuciauskas, Pat Dippo, Amit Munshi, and W. S. Sampath. “Sputter-Deposited Oxides for Interface Passivation of CdTe Photovoltaics.” IEEE Journal of Photovoltaics 8, no. 2 (2018): 587-593. In yet another embodiment, oxides including, but not limited to, SnO₂, which can be used with or without necessary and sufficient doping with other elements in order to produce desired results. The doping in SnO₂ layer can be elements such as but not limited to Zn and Mg. Some results using this method have shown promising results. Deposition of such a layer can be included by glass manufacturer and that would reduce manufacturing time while increasing manufacturing output.

In further examples, oxides including, but not limited to, SiO₂ and MgₓZn₁₋ₓO may be used, separately or in combination, in order to produce desired results. For example, adding a thin layer of SiO₂ with MgₓZn₁₋ₓO on the front surface may improve the fill factor, and thusly may improve the font interface. The MgₓZn₁₋ₓO that acts as an emitter/buffer has a passivating effect on the front interface. Owing to its appropriate band alignment with CdSeₓTe₁₋ₓ and CdTe, its use in CdTe has been demonstrated for efficiencies exceeding 20%. Introducing a few nanometer thin SiO₂ layer between the MgxZn1-xO and the absorber has shown improvement in the fill-factor that leads to improvement in efficiency. Without being limited to any one theory, this may be caused by the band alignment of SiO₂ that acts as a carrier selective layer leading to improved charge transport. Either of these layers can be used either independently or in combination with other oxide/passivating/carrier selective layers.

The back surface may include similar layers and carrier selectivity/passivation for higher device performance. In an example, a passivating oxide layer on the back surface may include MgO, which has shown distinct signs of passivation with PL measurement. Other potential back surface oxide layers include but are not limited to MgₓZn₁₋ₓO, MoOₓ, Al₂O₃, CuAlO₂, CuₓAl_{y}O, TeOₓ, etc. Such a layer may lead to improved passivation and reduce or eliminate charge recombination at this interface.

In at least one example, oxide layers can be disposed on a front-surface and a back-surface of an absorber layer. As used herein, the “front-surface” or “front interface” and “back-surface” or “back interface” oxide layers are described relative to the absorber/semiconducting material. The term “deposition” as used herein, refers to the act of depositing a first material onto a second material. As described above, the absorber layer can be a semiconducting material. The front-surface and back-surface oxide buffer can be used to improve the efficiency of the contact grids within the solar cell device.

In accordance with aspects of the disclosure, in at least one exemplary embodiment, a front-interface oxide layer of, e.g., Al₂O₃ can be disposed on a CdTe based solar cell at about 2 nm to about 20 nm, about 2 nm to about 10 nm, about 2 nm to about 5 nm, about 2 nm, about 5 nm, about 10 nm, etc. in thickness. In this regard, use of a thinner oxide layer at the back surface of the semiconductor layer, together with p+ layers has shown that thinner layers of the front-interface oxide layer (e.g., Al₂O₃) can be used to yield improvement in device performance. In certain aspects of the present disclosure, it was unexpectedly found that deposition of oxides such as, but not limited to Al₂O₃ at the front interface instead of more traditional oxides, e.g., MgZnO, can be used in accordance with aspects of the disclosure, to yield improvements in device performance. For instance such front interface oxides may achieve higher recombination lifetime while maintaining or improving the photovoltaic performance of the solar cell.

In the preparation of solar cells in accordance with the present disclosure, p+ layers can be deposited onto a substrate in order to assist in the increasing the efficiency of the solar cell device. For example, another carrier selective and/or highly p doped (p+ layer) may be included to allow improved extraction of charge carriers. In at least one embodiment, a solar cell can have a single p+ layer. In an alternative embodiment, a solar cell can have multiple p+ layers. For example, the p+ layer may be on the back surface of the semiconducting/absorber layer. An oxide layer may then be further deposited on the p+ layer. The p+ layer described herein can include, but is not limited to, highly doped amorphous silicon, NiO doped with Cu, or Te. Silicon doping can be used to adjust the band-alignment of the solar cell in order to produce a cell having a more favorable arrangement for charge collection within the cell. For example, use of a p+ amorphous silicon layer disposed on an Al₂O₃ layer can improve the open-circuit voltage of the resulting solar cell. Deposition of oxides, including those described in detail above, at the front interface can be used to achieve a higher recombination lifetime and maintain the photovoltaic performance of the cell.

In an embodiment, NiO doped with Cu may be used as the p+ layer. In some embodiments, only doping the absorber with arsenic may not be sufficient and thus may need a greater upwards bending of the energy bands. In some aspects, this may be done using a thin layer with higher doping and activation of group V dopant such as arsenic or by doping the back layer with copper. Copper in such devices has been known to cause problems by creating defects in the bulk of the absorber and/or causing recombination that the back interface. It is further envisioned that to overcome this potential limitation, the addition of a thin layer of NiO before depositing Cu for contacting may counter this issue pertaining to diffusion/drifting of Cu. Arsenic doping as well as Cu deposition post NiO is stable when exposed to high temperatures and a structure such as this can be treated with CdCl₂ or any other passivation heat treatment after all the layers are deposited with no detrimental effect.

In an embodiment, the deposition of a thin layer of TeOₓ followed by a layer of Te may have a comparable effect to that of doping with Cu or As. However, this process does not require active doping within the film, leading to higher field longevity. Furthermore, since there is no active dopant required in the device fabrication, it may significantly reduce the complexity of fabrication making it faster and cheaper.

In some embodiments, the solar cells may include transparent back contacts to provide bifaciality of CdTe thin film solar cells. In some aspects, using NiO:Cu at the back of TeOₓ instead of, or in addition to Te, may lead to better performance. Moreover, NiO:Cu is more than 80% transparent at the thicknesses required for such devices, thus providing the potential for a fully functional bifacial solar cell. Additionally, such a transparent contact layer may also be used as an intermediate TCO for fabrication of a tandem or multijunction solar cell structure. A solar cell device with NiO:Cu at the back of TeOx may or may not have ternary alloying with CdTe.

The methods and solar cells of the present disclosure have the potential to produce up to 20% more power as compared to existing solar panels of same capacity. This may lead to a major reduction in the balance of systems costs. Furthermore, the oxide passivation layer may lead to higher efficiency with open-circuit voltage >900 mV.

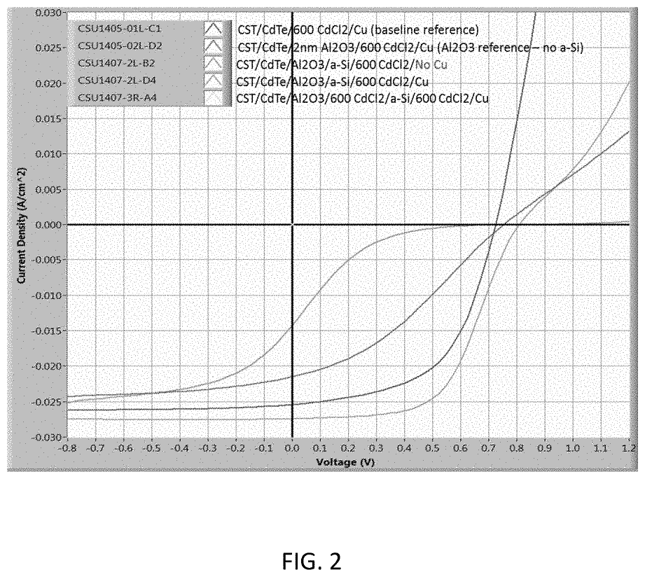

Solar cells made in accordance with the present disclosure have illustrated that a CdCl₂ passivation treatment and CuCl doping can be effectively used to produce a solar cell having improved features, as indicated in the graph provided in FIG. 1. As illustrated, the performance of the resulting solar cell device can be altered by merely changing the number of layers or the sequence in which treatment layers are applied. Specifically, FIG. 2 illustrates significant improvement in both the open-circuit voltage and efficiency of a solar cell having an Al₂O₃ and p+ a-Si layer deposited onto the semiconducting material after a CdCl₂ passivation and CuCl₂ doping treatment.

A chart relating to the graphical data is provided below in Table 1.

TABLE 1

| | | | V_{oc} | Fill Fac | J_{sc} | Eff | Cell Area | Vₘₚ | Jₘₚ |
|---|---|---|---|---|---|---|---|---|---|
| Run | Plate | Device | [mV] | [%] | [mA/cm²] | [%] | [cm²] | [mV] | [mA/cm²] |
| 1405 | 01L | C1 | 725 | 55.1 | 25.4 | 10.14 | 0.693 | 519 | 19.5 |
| 1405 | 02L | D2 | 754 | 33.9 | 21.5 | 5.49 | 0.704 | 400 | 13.7 |
| 1407 | 2L | B2 | 817 | 9.0 | 14.3 | 1.05 | 0.634 | 162 | 6.5 |
| 1407 | 2L | D4 | 808 | 56.4 | 27.4 | 12.48 | 0.629 | 533 | 23.4 |
| 1407 | 3R | A4 | 1175 | −69.4 | −0.0 | 0.00 | 0.695 | −800 | −0.0 |

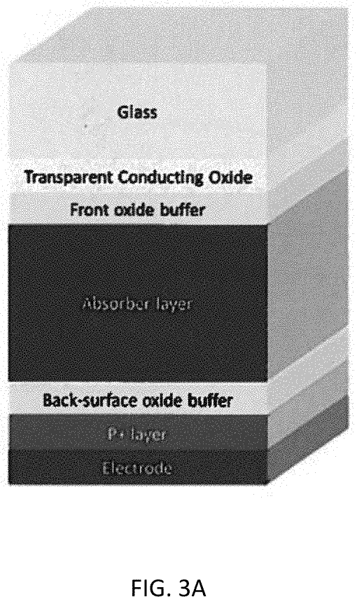

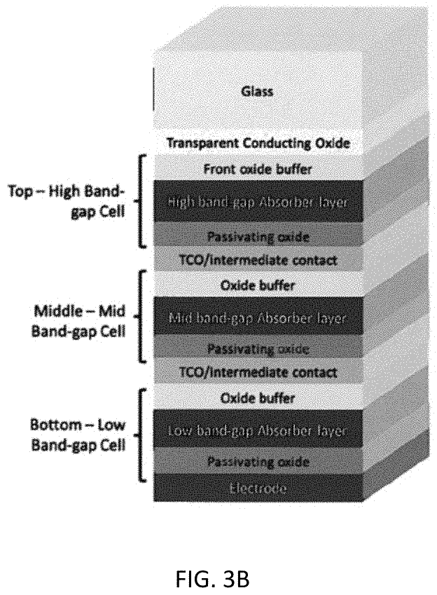

Examples of single junction and multi junction solar cells are illustrated in FIGS. 3A and 3B. Specifically, FIG. 3A illustrates a schematic diagram of an exemplary single junction device. For the purposes of this example, the relative size of each of the layers illustrated in FIG. 3A are not considered to be to scale. The device of FIG. 3A is a single junction having a single oxide and p+ layer. Specifically, the exemplary solar cell device includes an electrode having a p+ layer disposed thereon, a back-surface oxide buffer, an absorber (semiconducting) layer, a front-surface oxide buffer, a transparent conducting oxide, and glass.

FIG. 3B illustrates a schematic diagram of an exemplary multi junction solar cell device; as with FIG. 3A, for the purposes of this example the layers illustrated are not considered to be to scale. The device of FIG. 3B includes multiple band-gap cells, passivating oxides, and buffers. Specifically, the solar cell device includes an electrode having three different band-gaps (top, middle, and bottom), a transparent conducting oxide (TCO), and glass. Each of the three gaps includes a passivating oxide, a semiconducting layer/absorber and an oxide buffer. The bottom, or low band, gap cell includes a passivating oxide, having a low band-gap absorber layer and oxide buffer disposed thereon; the middle, or mid band, gap cell also includes a passivating oxide having a mid band-gap absorber layer and oxide buffer disposed thereon; and the top, or high band, gap cell includes a passivating oxide, high band-gap absorber layer, and front oxide buffer disposed thereon. A TCO/intermediate contact layer can be located between the bottom and middle cells, as well as between the middle and top cells.

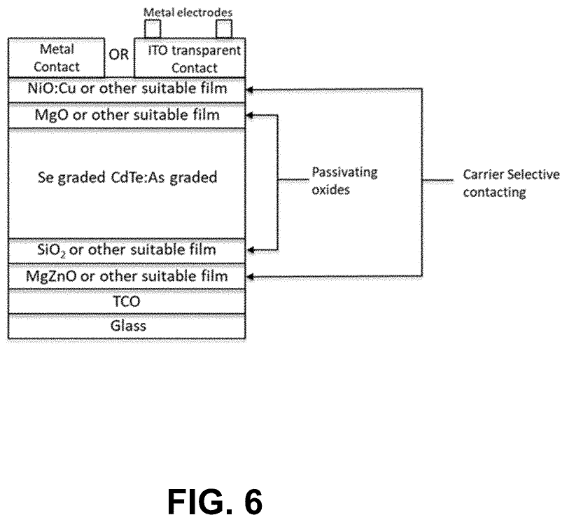

FIG. 6 illustrates a schematic diagram of an exemplary solar cell device. For the purposes of this example, the layers illustrated are not considered to be to scale. The device of FIG. 6 includes a semiconducting/absorber layer with passivating oxide layers and carrier selective contacting layers on both the front surface and the back surface of the semiconducting/absorber layer. In some embodiments, the front surface of the semiconducting/absorber layer includes a first passivating oxide layer, a first carrier selective contact layer, a TCO, and glass. In an example, the first passivating oxide layer may include SiO₂ or other suitable films. In another example, the first carrier selective contact layer may include MgZnO or other suitable films. In some embodiments, the back surface of the semiconducting/absorber layer may include a second passivating oxide layer, a second carrier selective contact layer/p+ layer, and an electrical contact. In an example, the second passivating oxide may include MgO or any other suitable film. In another example, the second carrier selective contact layer/p+ layer may include NiO:Cu or any other suitable film. In additional examples, the electrical contact may be a metal contact or metal electrodes on an ITO transparent contact.

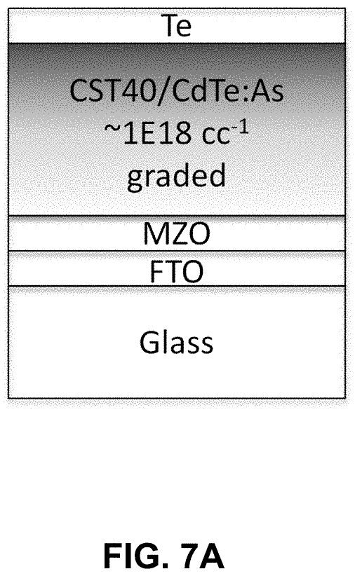

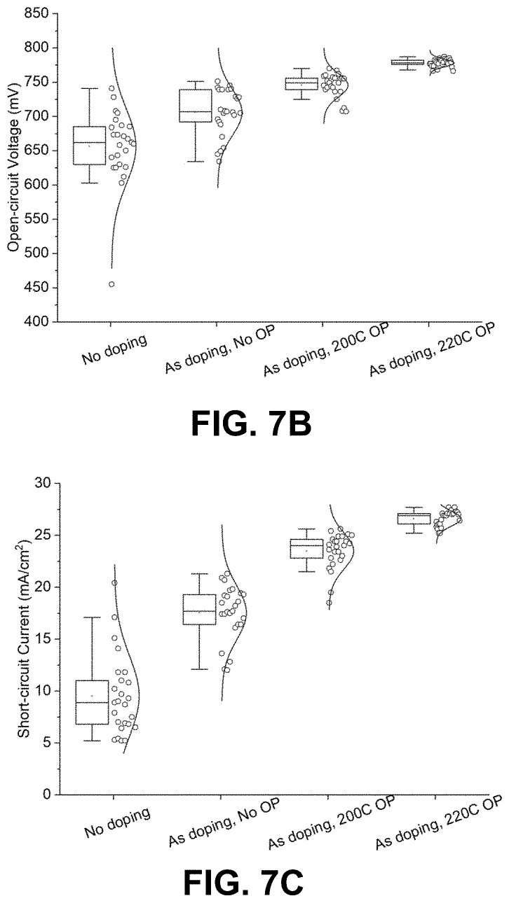

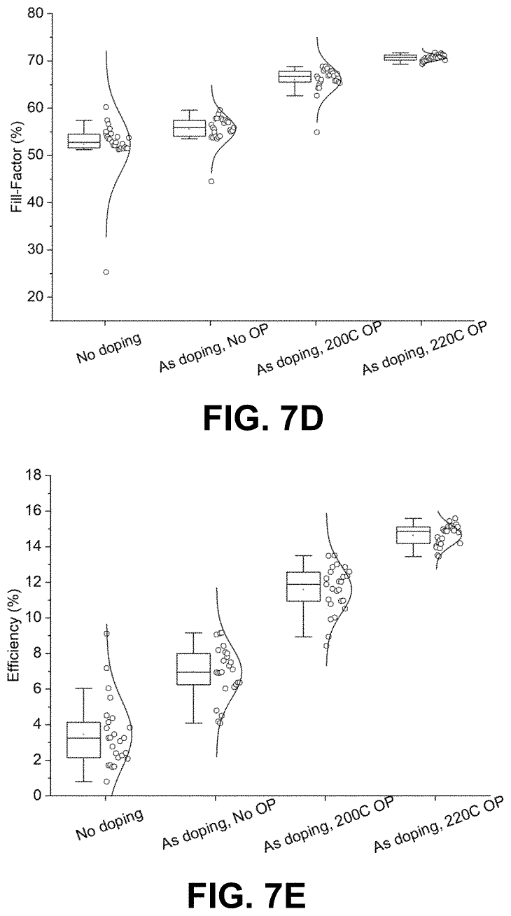

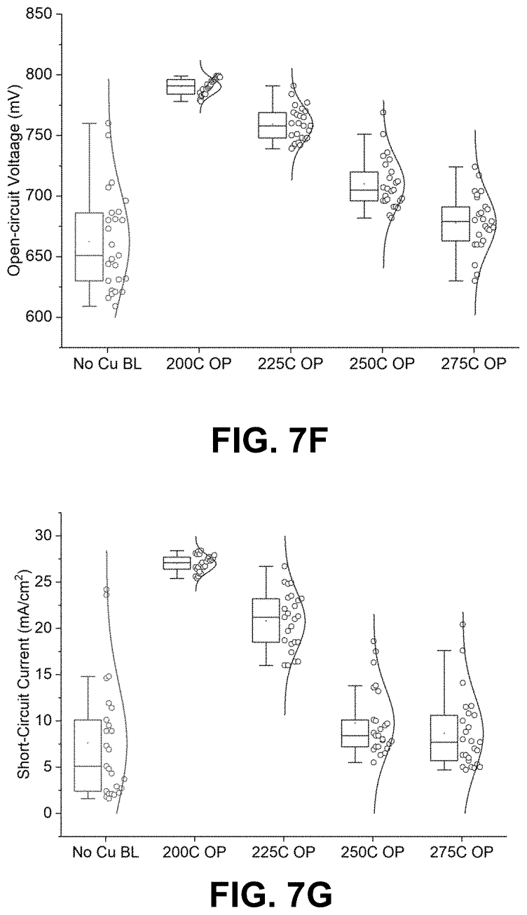

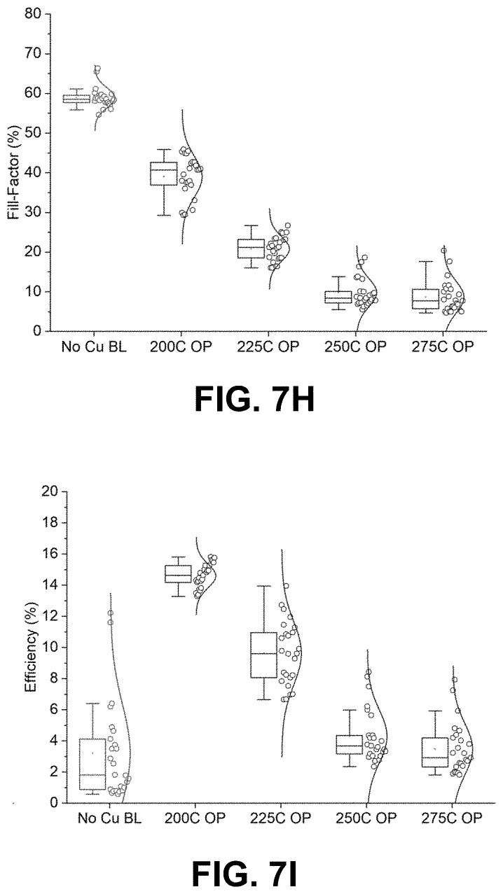

FIGS. 7A, 8A, 10A, 11A, 12A, 13A, and 14A illustrate schematic diagrams of exemplary alternative solar cells and/or intermediate solar cells used in the design of the solar cell of FIG. 6.

In an embodiment, FIG. 7A illustrates an exemplary solar cell including an MZO layer, an FTO layer, and glass on the front surface of the CST40/CdTe:As absorber layer and Te on the back surface of the absorber layer. The absorber layer is about 1E18 cc⁻¹ graded. In some examples, the solar cell of FIG. 7A was used for testing the optimization of Cd overpressure for As doping. Cadmium overpressure may range from about 200° C. to 275° C. In one example, the Cd overpressure for As doping may be at about 210° C.

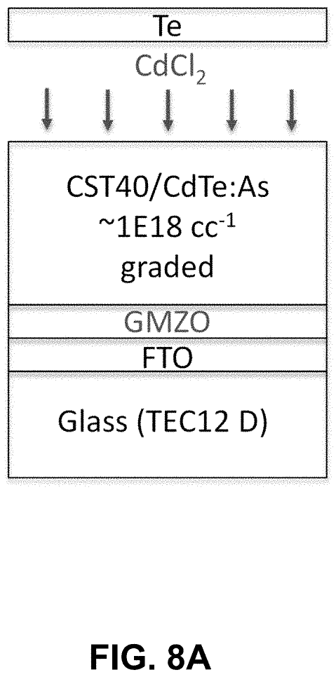

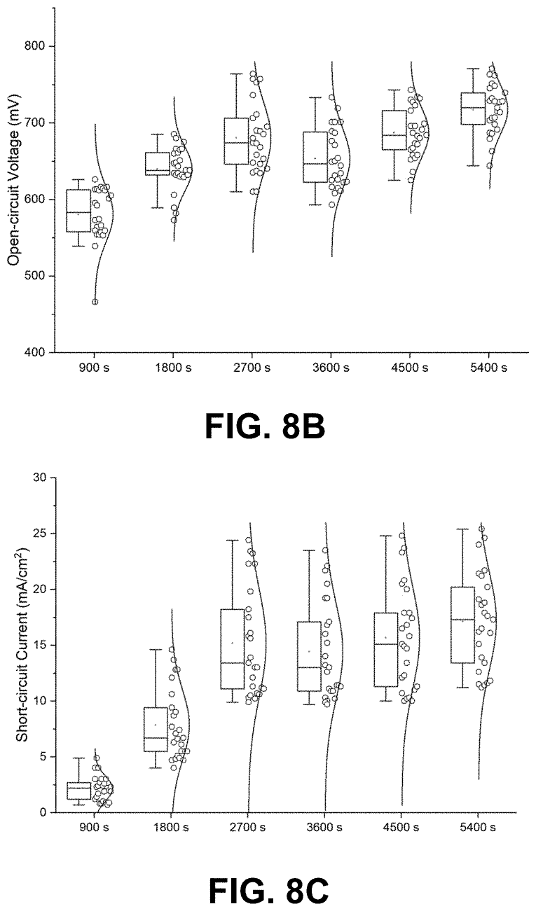

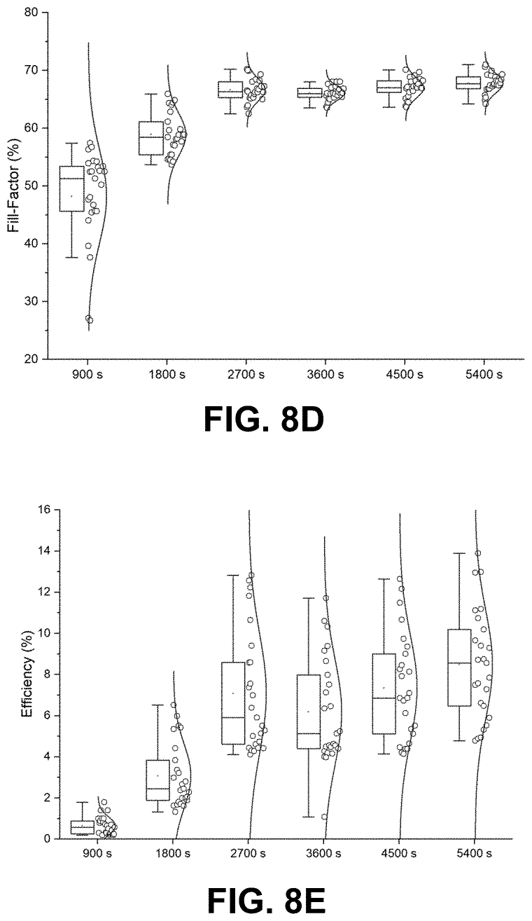

In an embodiment, FIG. 8A illustrates an exemplary solar cell including a GMZO layer, an FTO layer, and glass on the front surface of the CST40/CdTe:As 1E18 cc⁻¹ graded absorber layer and Te treated with CdCl₂ on the back surface of the absorber layer. In some examples, the solar cell of FIG. 8A was used for testing the effect of CdCl₂ treatment time. In some embodiments, the CdCl₂ treatment time may range from about 900 s to about 5400 s. In one embodiment, the CdCl₂ treatment is performed up to about 460° C. The extended treatment time shows that the solar cell is not negatively affected by temperature and can withstand long periods of heat as well as field conditions. Without being limited to any one theory, this may suggest these solar cells are more tolerant to changes in processing as well as have longer life in field. In contrast, current solar cells typically degrade by exposure to 200° C. for a few minutes.

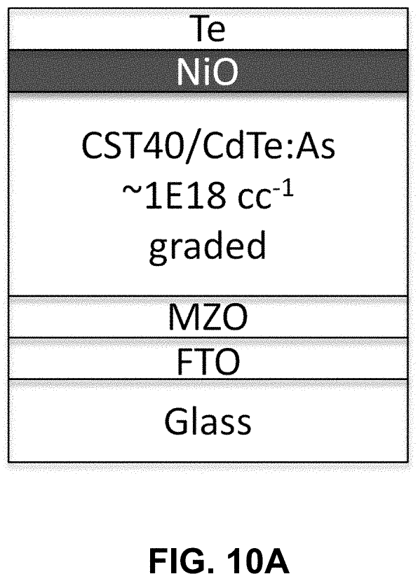

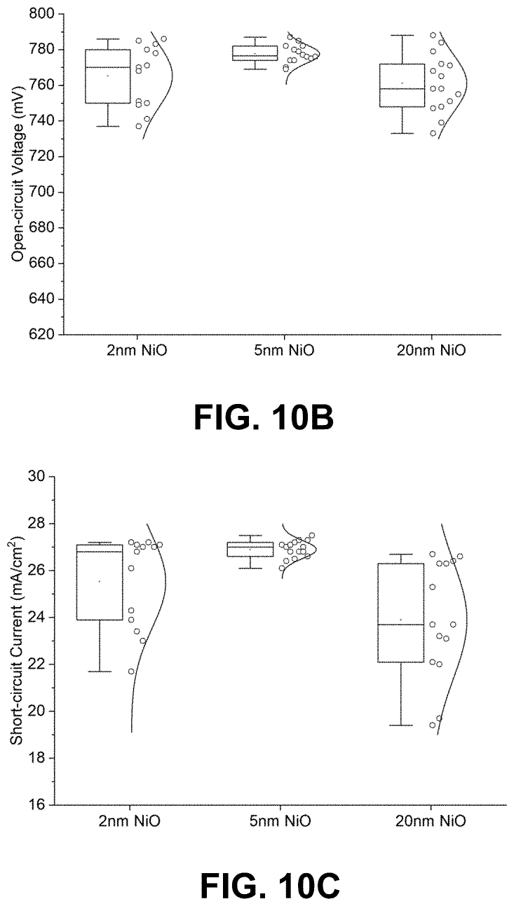

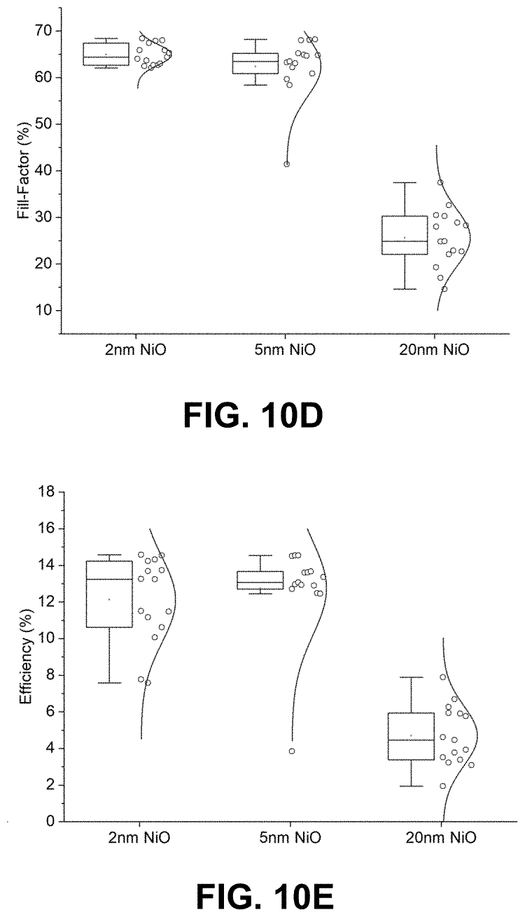

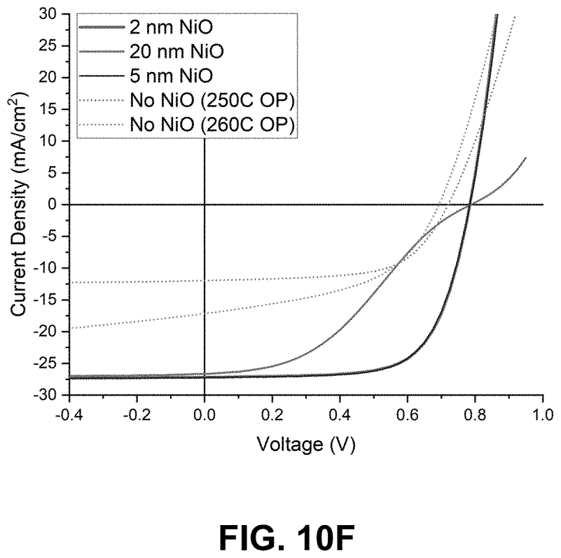

In an embodiment, FIG. 10A illustrates an exemplary solar cell including an MZO layer, an FTO layer, and glass on the front surface of the CST40/CdTe:As 1E18 cc⁻¹ graded absorber layer and a NiO layer and a Te layer on the back surface of the absorber layer. In some examples, the solar cell of FIG. 10A was used for testing the improvement of CdTe:As devices with NiO contacts. In various aspects, the NiO layer may range from about 2 nm to about 20 nm in thickness. Therefore, it may be desired for the NiO layer to be 5 nm, 2 nm, or between 5 nm and 2 nm in thickness.

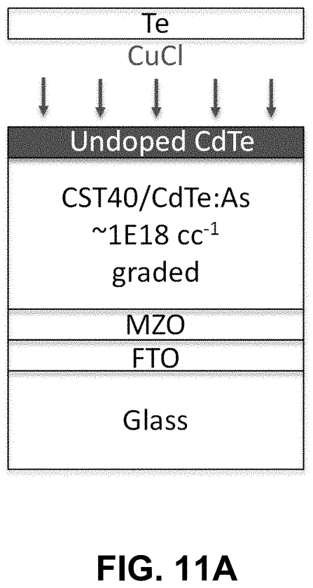

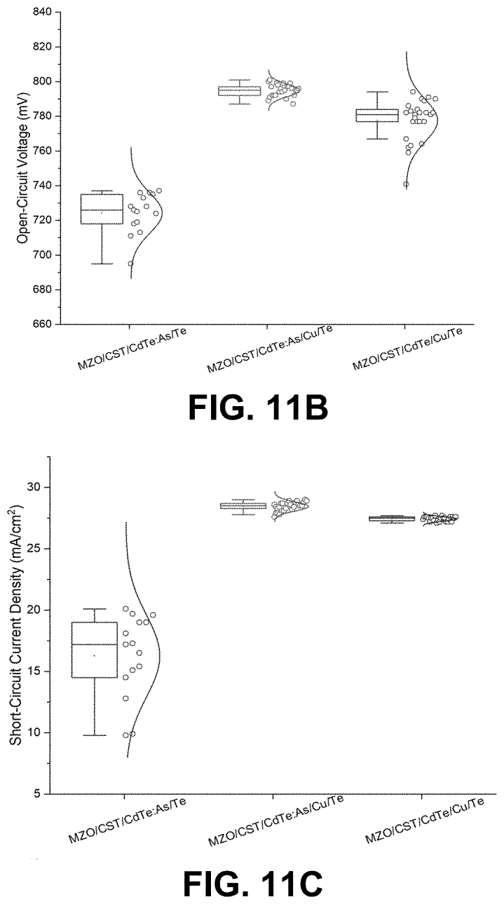

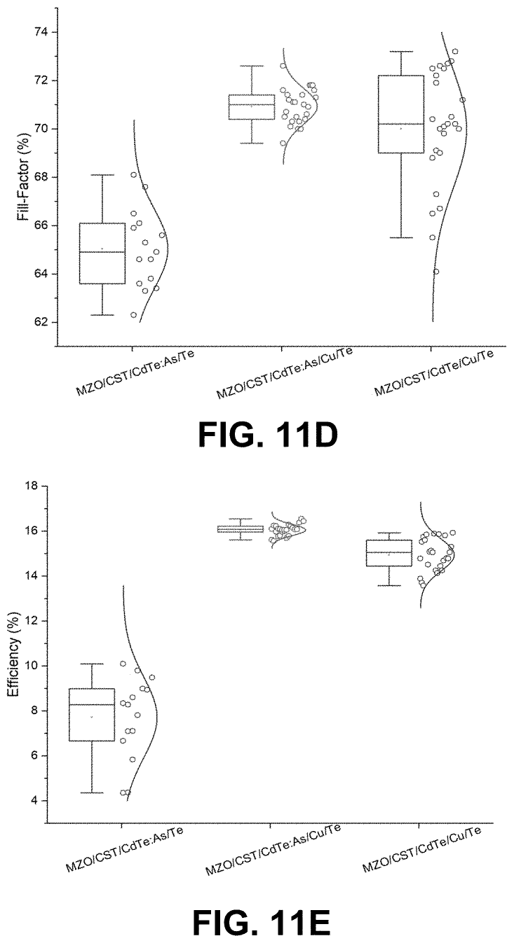

In an embodiment, FIG. 11A illustrates an exemplary solar cell including an MZO layer, an FTO layer, and glass on the front surface of the CST40/CdTe:As 1E18 cc⁻¹ graded absorber layer and an undoped CdTe layer with a CuCl treatment and a Te layer on the back surface of the absorber layer. In some examples, the solar cell of FIG. 11A was used for testing doping with arsenic and copper treatment.

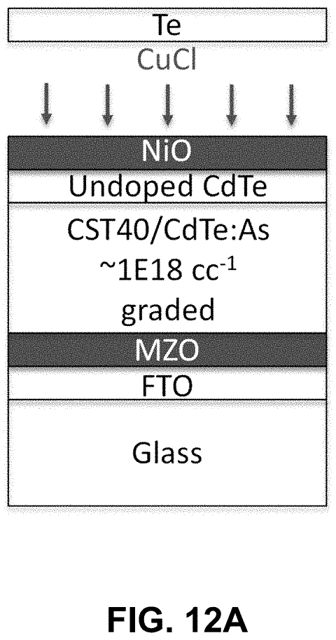

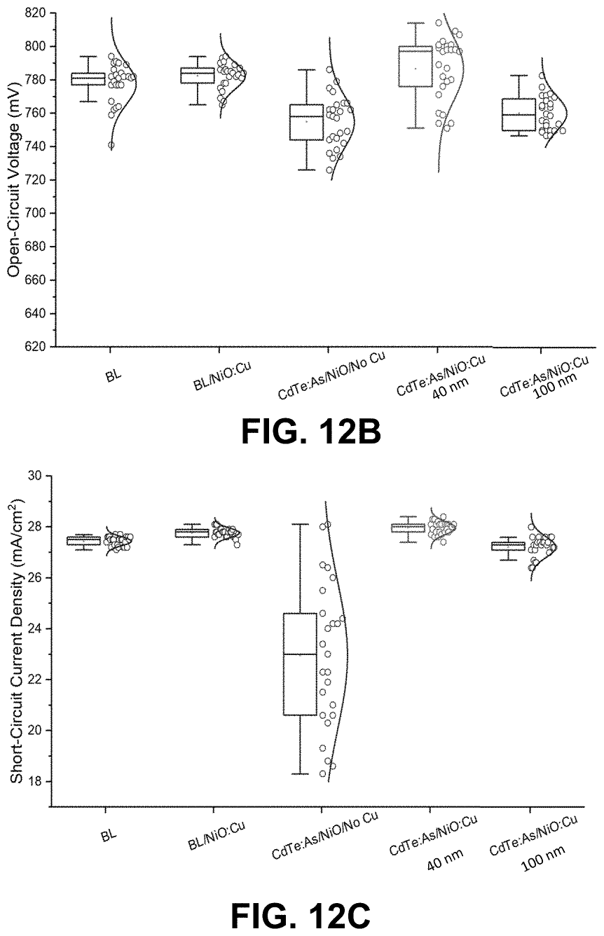

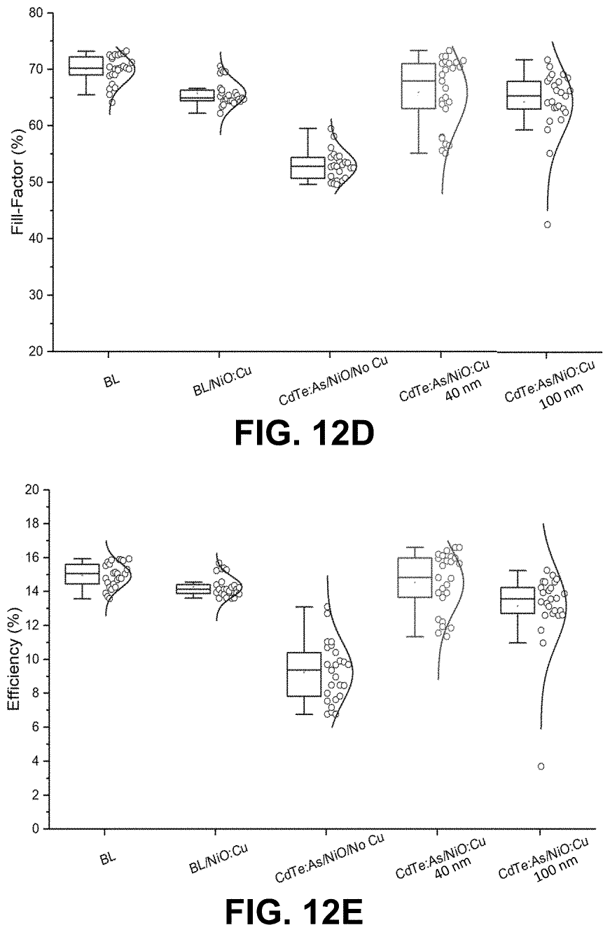

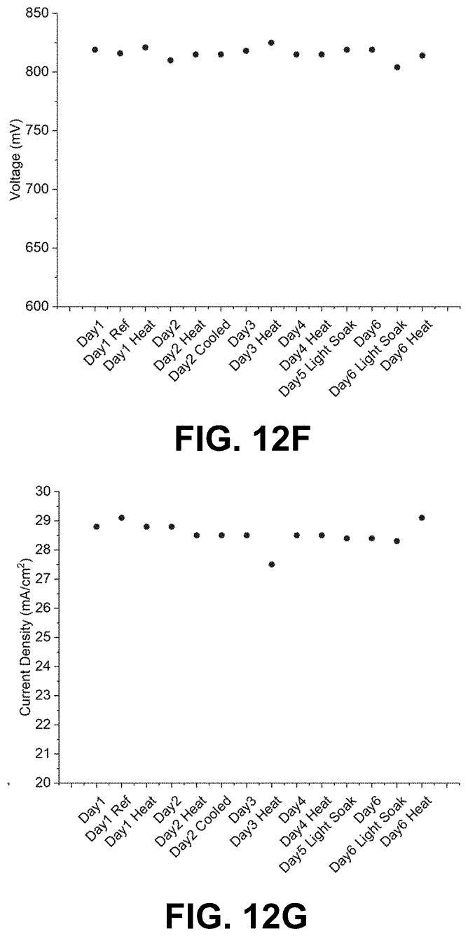

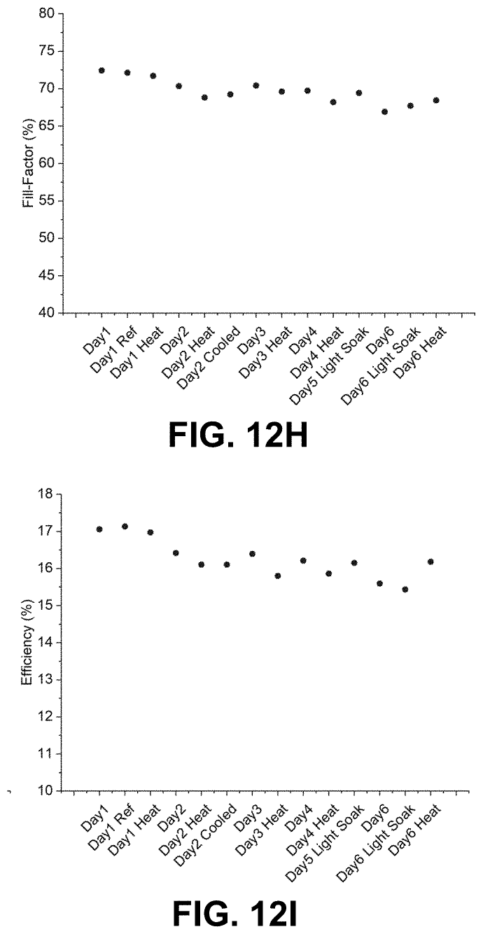

In an embodiment, FIG. 12A illustrates an exemplary solar cell including an MZO layer, an FTO layer, and glass on the front surface of the CST40/CdTe:As 1E18 cc⁻¹ graded absorber layer and an undoped CdTe layer, a NiO layer with a CuCl treatment, and a Te layer on the back surface of the absorber layer. In some examples, the solar cell of FIG. 12A was used for testing arsenic doping with NiO/NiO:Cu and the effect on MZO thickness. The thickness of the MZO layer may range from 2 nm to 100 nm, 1 nm to 40 nm, or 40 nm to 100 nm.

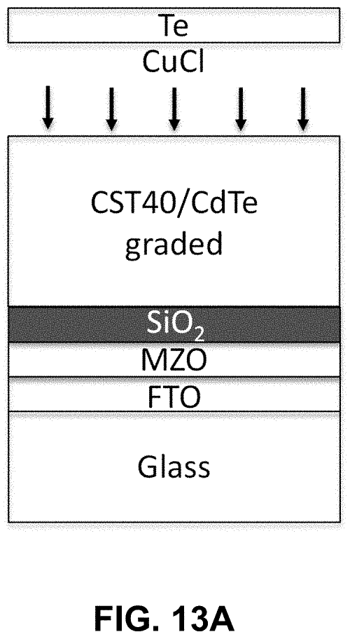

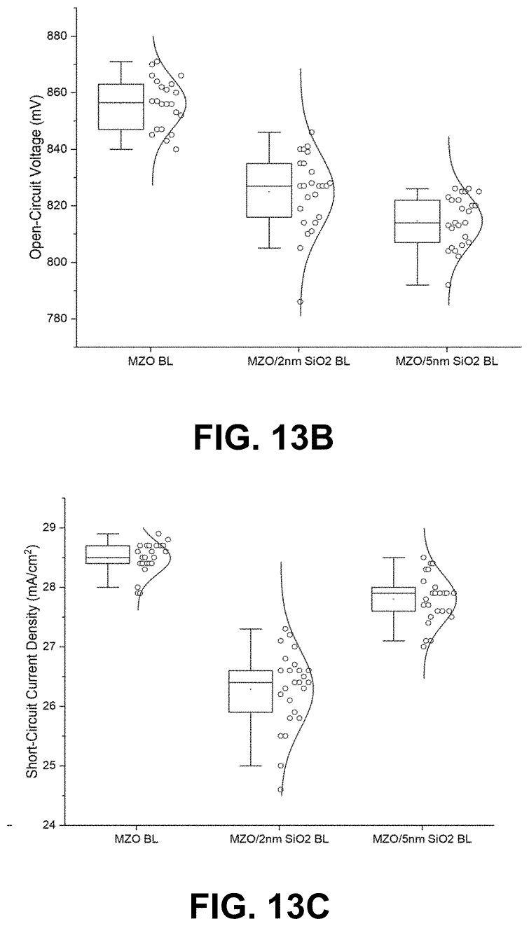

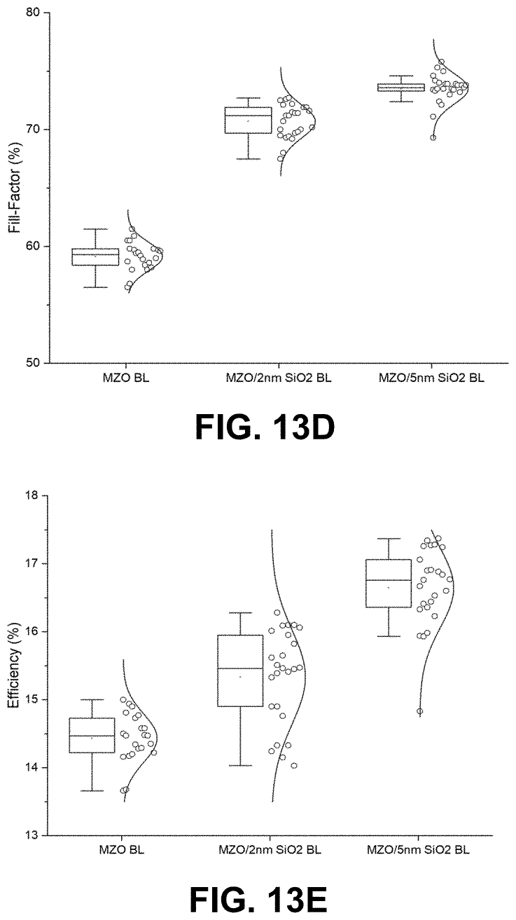

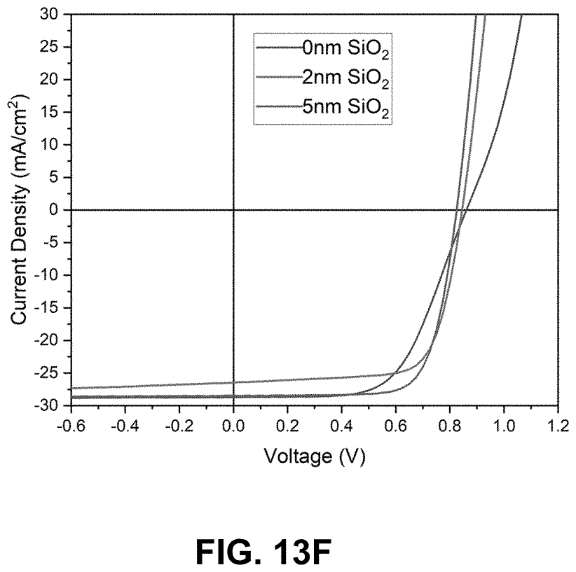

In an embodiment, FIG. 13A illustrates an exemplary solar cell including an SiO₂ layer, an MZO layer, an FTO layer, and glass on the front surface of the CST40/CdTe graded absorber layer with a CuCl treatment and a Te layer on the back surface of the absorber layer. In some examples, the solar cell of FIG. 13A was used for testing SiO₂ with MZO for better front interface passivation. In various aspects, the SiO₂ layer may range from about 2 nm to about 20 nm or about 2 nm to about 5 nm in thickness. For example, the SiO₂ layer to be about 5 nm, 2 nm, less than or equal to 5 nm, or between 5 nm and 2 nm in thickness.

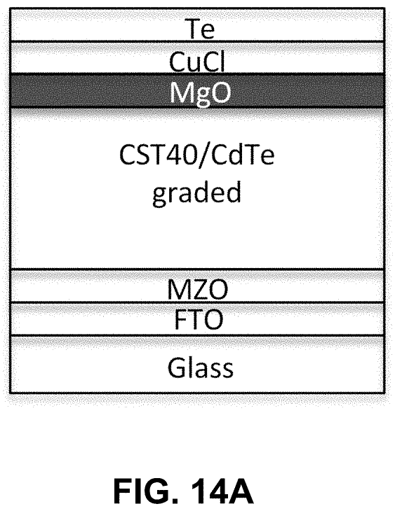

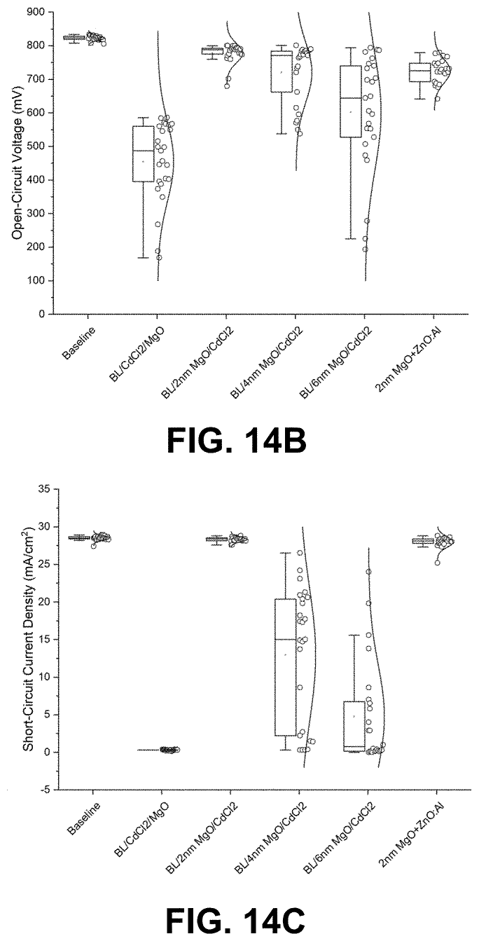

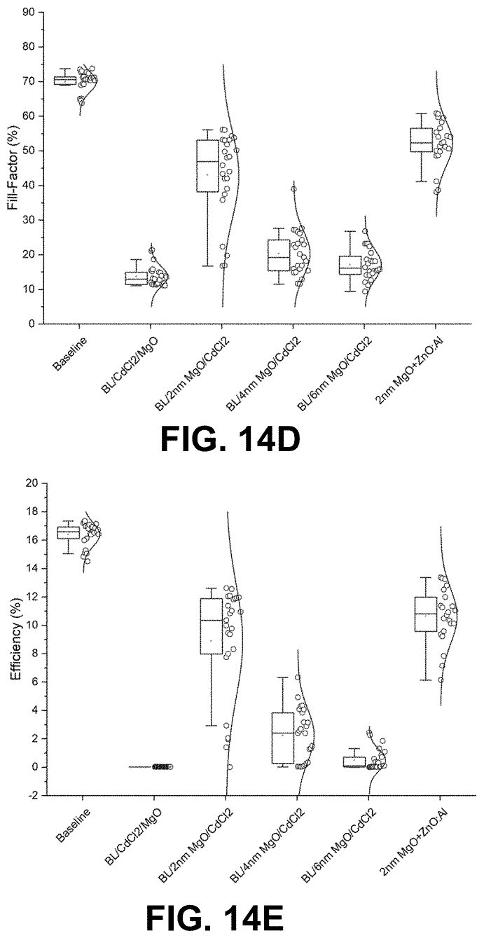

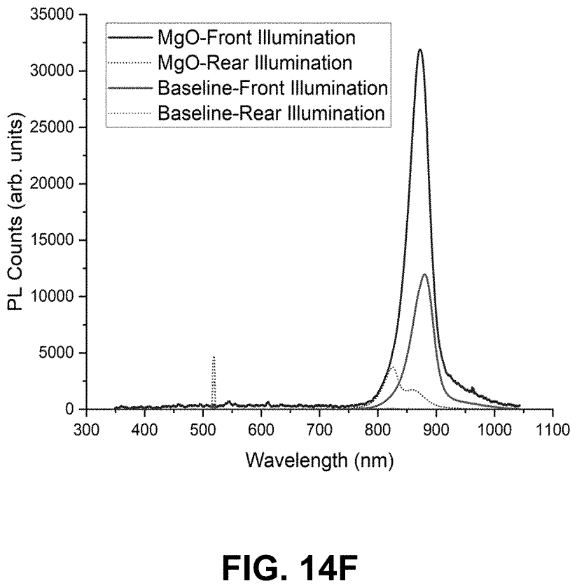

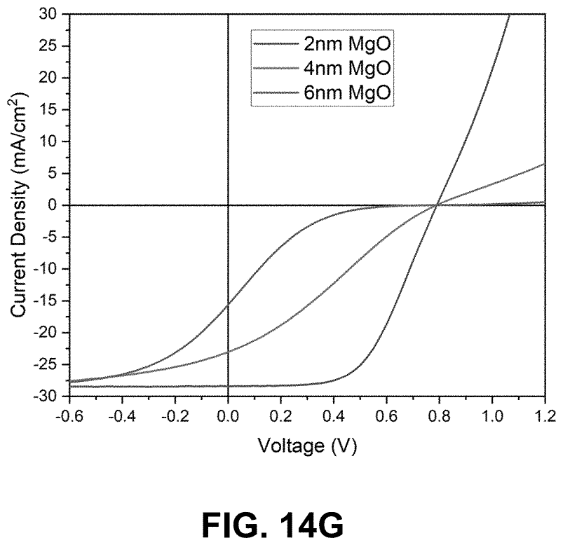

In an embodiment, FIG. 14A illustrates an exemplary solar cell including an SiO₂ layer, an MZO layer, an FTO layer, and glass on the front surface of the CST40/CdTe graded absorber layer and an MgO layer, a CuCl layer, and a Te layer on the back surface of the absorber layer. In some examples, the solar cell of FIG. 14A was used for testing MgO for back surface passivation. In various aspects, the MgO layer may range from about 2 nm to about 20 nm, about 2 nm to about 6 nm, or about 2 nm to about 4 nm in thickness. For example, the SiO₂ layer to be about 6 nm, 4 nm, 2 nm, less than or equal to 6 nm, or between 6 nm and 2 nm in thickness.

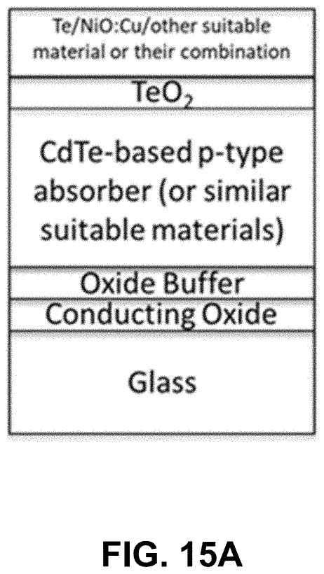

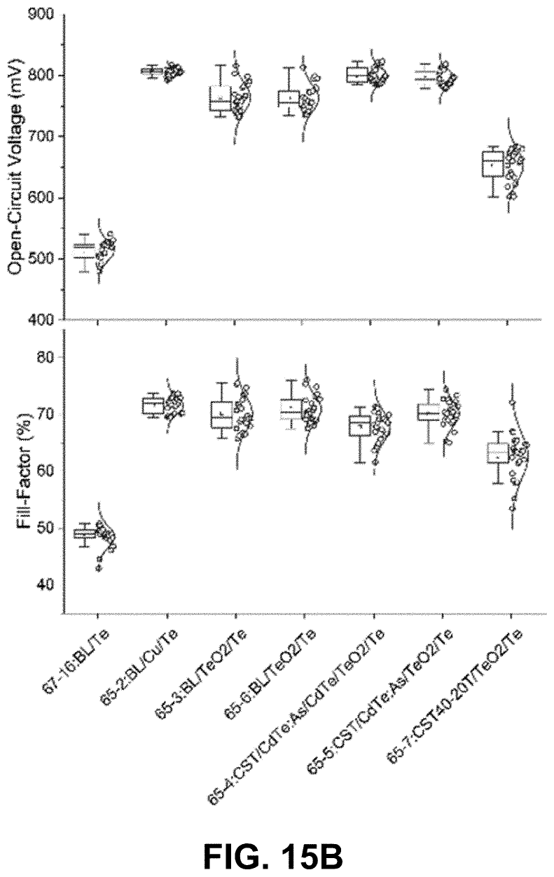

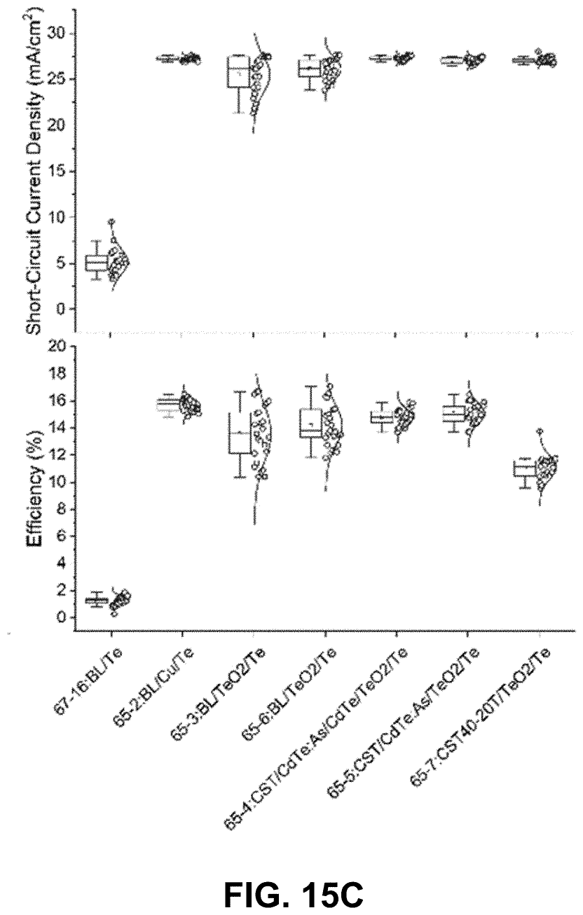

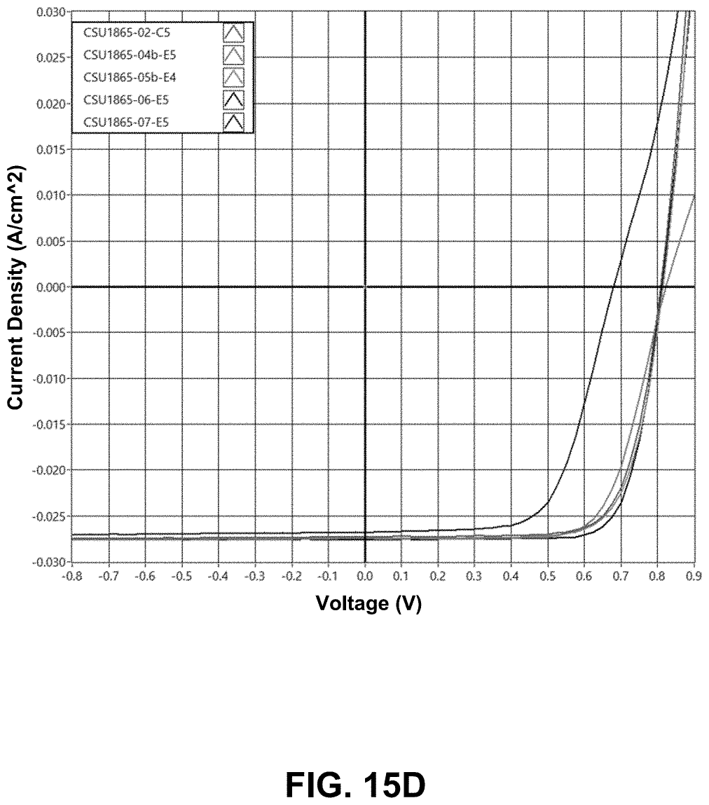

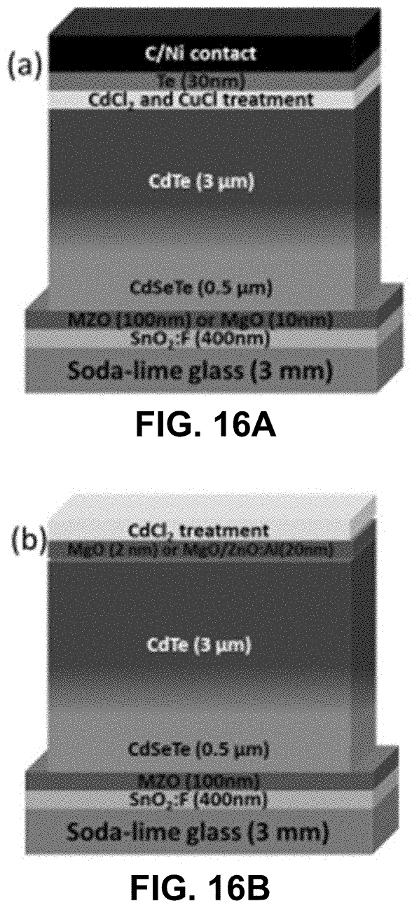

FIG. 15A illustrates a schematic diagram of an exemplary solar cell device. For the purposes of this example, the layers illustrated are not considered to be to scale. The device of FIG. 15A includes a semiconducting/absorber layer with one or more oxide layers on both the front surface and the back surface of the semiconducting/absorber layer. In some embodiments, the front surface of the semiconducting/absorber layer includes an oxide buffer layer, a conducting oxide layer, and glass. In some embodiments, the back surface of the semiconducting/absorber layer may include a TeO₂ layer and a carrier selective contact layer/p+ layer. In an example, the carrier selective contact layer/p+ layer may include Te, NiO:Cu, any other suitable film, or combinations thereof.

In at least one embodiment, a layer of zinc telluride (ZnTe) can be deposited on the back-surface of the solar cell device. The ZnTe layer can assist in producing favorable band alignment throughout the cell. In said example, the solar cell device can also be doped with a dopant, such as copper, to improve PL intensity and reduce voltage deficit within the cell. In at least one example, solar cell devices having a ZnTe layer can be passivated with zinc chloride (ZnCl₂), to produce a solar cell showing superior energy performance. Passivation treatments as described herein including, but not limited to, those done with passivating chemicals such as CdCl₂ (or other chlorides such as but not limited to MgCl₂, ZnCl₂, MnCl₂, etc. or other compounds of cadmium with halogens such as cadmium fluoride, cadmium bromide, cadmium iodide, etc.), can be used to produce high efficiency thin-film solar cells, and can be re-optimized based on the incorporation of one or more oxide layers. Furthermore, solar cells produced in accordance with the present disclosure, have been shown to have a higher efficiency when CdCl₂ is passivated onto the oxide layer.

In an embodiment, the passivating chemical may be sublimed onto the deposited film following which the substrate/superstrate may be annealed in vacuum at a temperature greater than about 450° C. for a few minutes followed by a shorter chemical passivation. Alternatively, the first chemical passivation may be a wet treatment performed in vacuum or in air, or in any other ambient conditions. A combination of the above stated passivating chemicals may also be used in sequence or as a mixture or both. In some embodiments, the resubliming material may be captured off the substrate/superstrate during the annealing treatment to recycle.

The thin-film solar cell device may or may not have ternary alloying with CdTe in the semiconducting/absorber layer. Additionally, in at least some embodiments, copper or arsenic can be used to dope the cadmium telluride (CdTe) based thin-film solar cells. The CuCl doping treatment can be used to dope the bulk material and form a back-surface contact on the semi-conducting material. Such contact can assist in achieving a higher efficiency by moving all, or part, of the contact grids to the rear of the solar cell device. While a copper or arsenic dopant is described in more detail, it would be obvious to those having skill in the art that other dopants can be used to treat the solar cell device. Suitable dopants can include, but are not limited to, copper, nitrogen, phosphorus, arsenic, antimony, and bismuth. The dopants described herein can be used to dope the bulk material of the semiconductor prior to the deposition of an oxide layer. The combination of doping the semiconducting material prior to deposition of an oxide layer, after the deposition of an oxide layer, and/or after the passivation treatment of the semiconducting material can improve the efficiency of the resulting solar cell. In other embodiments, the oxide layer deposited on the semiconductor layer may allow the semiconducting/absorber layer to be used without doping.

In some aspects, an arsenic dopant in the absorber may be appropriately graded and the dopant efficiently activated by depositing a selenium alloyed CdTe in the front followed by CdTe:As and then treating it with CdCl₂. This may cause arsenic to get in the Se alloyed region through interdiffusion/mixing and may lead to a highly activated arsenic dopant in the absorber.

However, lower field longevity of such panels in the field is due to the mobility of the dopant. In certain embodiments, the CdTe may not be doped. Instead, a thin layer of TeOx followed by a layer of Te may have a comparable effect to that of doping with Cu or As. As discussed herein above, adding a NiO:Cu layer to the TeOₓ may further improve the performance of the solar cell.

Moreover, both doping and passivation treatments can have a significant impact on the electrodes present within the solar cell. As such, the particular electrode used within the solar cell must be considered when selecting materials to use in either a dopant or a passivation treatment. Electrodes that can be altered by doping and passivation treatments as described herein can include transparent, translucent, and opaque electrodes. Suitable electrodes can be metallic or non-metallic in nature. Specifically, materials that can be used as described herein can include, but are not limited to, metals (including, but not limited to, nickel, gold, and aluminum), semi-conducting materials or metalloids (including, but not limited to, tellurium), and non-metals (including, but not limited to, nickel oxide, doped tin oxide, and graphite).

As described with respect to FIGS. 3A-3B, the methods described herein can be used to produce both single junction and multi junction solar cells. Multi junction solar cells produced in accordance with the present disclosure can include both high band-gap solar cells and low band-gap solar cells. The high and low band-gap solar cells can have similar device structures as those described in detail above. In addition to producing high and low band-gap solar cells, the methods described herein can be used separately or in tandem in order to achieve an increased solar cell output.

For example, higher band-gap solar cells can be fabricated using alloy compositions including, but not limited to, cadmium magnesium tellurium (CdₓMg₁₋ₓTe) and cadmium zinc tellurium (CdₓZn₁₋ₓTe). The oxide layers, doping treatments, and passivation treatments described above can be used where appropriate to optimize the materials present in the solar cell to produce high efficiency thin-film solar cells having a higher band-gap.

In an alternative example, a lower band-gap solar cell can be fabricated using an alloy compositions including, but not limited to, cadmium magnesium tellurium (CdₓHg₁₋ₓTe). As described above, various materials can be used to optimize the solar cell device by applying oxide layers, doping treatments, and passivation treatments to produce a high efficiency thin-film solar cell having lower band-gap.

In yet another alternative example, low band-gap, mid-band gap, and high band-gap cell structures can be fabricated in tandem using a variety of intermediate contacts in order to form a multi junction solar cell having a higher efficiency than each of the individual solar cells within the multi junction structure. As described in detail above, an example of an exemplary multi-junction solar cell is illustrated in FIG. 3B.

In an even further example, a CdTe-based p-type absorber may be bandgap engineered using selenium (Se), for example as seen in FIG. 6. Use of selenium may have a passivation effect in addition to the bandgap grading. Furthermore, greater selenium proportion may lead to better activation of group V element doping and thus higher carrier concentration. Therefore, appropriate incorporation and grading of selenium may be employed for activation of dopants, such as arsenic.

In certain embodiments, band gap engineering with Se may be accomplished using a CdSeₓTe₁₋ₓ ternary source charge followed by deposition of CdTe or CdTe:As or their combination and then performing an appropriate heat/passivation treatment with or without the presence of CdCl₂ (or other Chlorides such as but not limited to MgCl₂, ZnCl₂, MnCl₂, etc. or other compounds of cadmium with halogens such as cadmium fluoride, cadmium bromide, cadmium iodide, etc.). In other embodiments, the band gap engineering with Se may be accomplished using a CdSe binary source charge followed by deposition of CdTe or CdTe:As or their combination and then performing an appropriate heat/passivation treatment with or without the presence of CdCl₂ (or other Chlorides such as but not limited to MgCl₂, ZnCl₂, MnCl₂, etc. or other compounds of cadmium with halogens such as cadmium fluoride, cadmium bromide, cadmium iodide, etc.). In additional embodiments, the band gap engineering with Se may be accomplished using a CdTe with co-sublimation of Se to form ternary CdSeₓTe₁₋ₓ alloy on the substrate/superstrate followed by deposition of CdTe or CdTe:As or their combination and then performing the appropriate heat/passivation treatment with or without the presence of CdCl₂ (or other Chlorides such as but not limited to MgCl₂, ZnCl₂, MnCl₂, etc. or other compounds of cadmium with halogens such as cadmium fluoride, cadmium bromide, cadmium iodide, etc.).

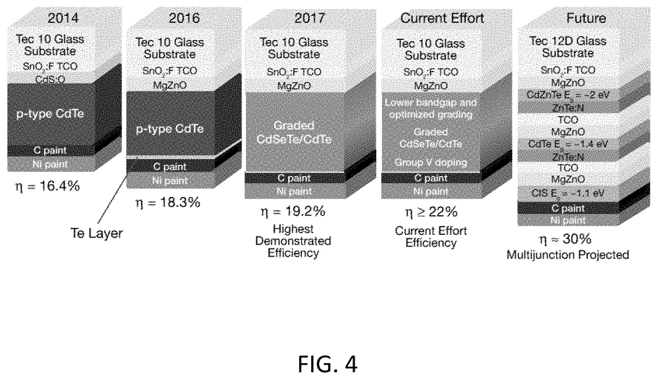

The processes and methods described herein can be shown to increase the efficiency of solar cells, as indicated in FIG. 4. Specifically, FIG. 4 illustrates a range of efficiencies from past functional solar cells to potential solar cells which can be created in the future using the methods described herein. Specifically, in 2014 an efficiency of 16.4% was possible; in 2016 it was increased to 18.3%. Using the methods and materials disclosed herein it has been demonstrated that a CdTe based thin-film solar cells having an efficiency of 19% was achieved. See., e.g., Munshi, Amit H., Jason Kephart, AliAbbas, John Raguse, Jean-Nicolas Beaudry, Kurt Barth, James Sites, John Walls, and Walajabad Sampath. “Polycrystalline CdSeTe/CdTe Absorber Cells with 28 mA/cm2 Short-Circuit Current.” IEEE Journal of Photovoltaics 8, no. 1 (2018): 310-314. The increase in efficiency can be traced to at least three major advances within the basic cell structure of a CdTe PV. For example, replacing a traditional cadmium sulfide (CdS) layer with a magnesium-doped zinc oxide layer significantly changed the properties of the resulting solar cell device. Specifically, MgZnO has a higher bandgap than CdS, allowing for more photons to reach the CdTe absorber layer. Additionally, MgZnO has a conduction-band offset that can help reduce interfacial recombination, preserving the voltage. Second, the incorporation of a Te layer at the back of the CdTe layer. The inclusion of a second Te layer can allow the solar cell device to yield an improved contact and higher efficiency. In accordance with aspects of the disclosure, it was found that CdTe thin-film solar cell efficiency can be improved to over 21% with open-circuit voltage of over 1V.

This improvement is indicated in the transition from the 2014 to the 2016 solar cell of FIG. 4. Such addition was able to produce an efficiency increase of nearly 2%. Finally, the introduction of an alloy layer of CdTe and CdSe, or CdSeTe, in front of the CdTe layer has allowed for significant improvements. Specifically, the CdSeTe layer has a smaller bandgap, enabling it to produce more currently. Additionally, the CdSeTe layer has a longer recombination lifetime than CdTe and can form an electric field in the favorable direction where the cell transitions from CdTe to CdSeTe. A cell made in accordance with this feature is indicated in the 2017 cell of FIG. 4, which is an exemplary embodiment of the present disclosure, indicating an increase to 19.2% efficiency.

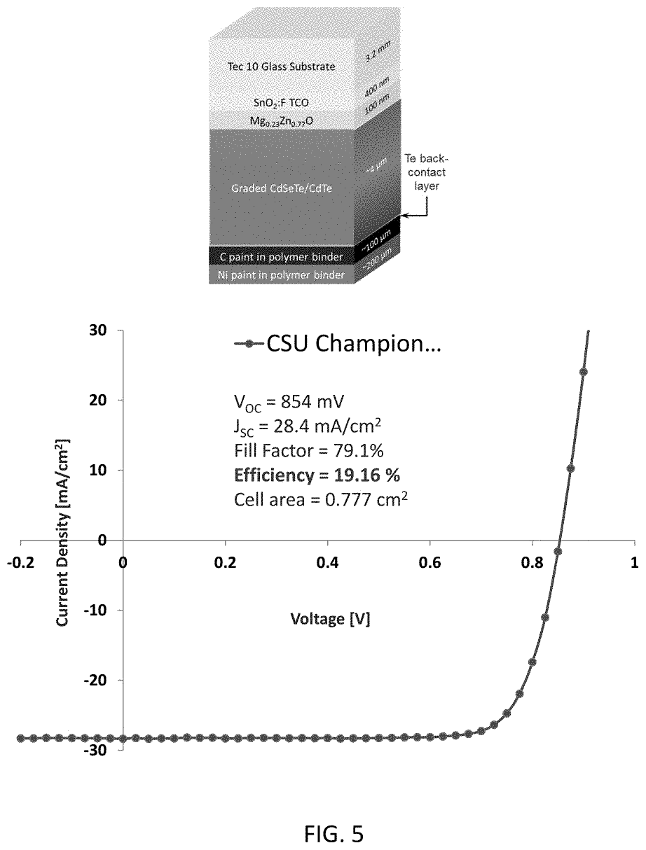

An enlarged view of the 2017 cell is shown in FIG. 5, along with a chart indicating the voltage and current density of the cell. As shown, the cell can produce a voltage of above about 0.8. As the methods described herein are improved, efficiencies above 20% are predicted to be possible, as indicated in FIG. 4.

As shown in FIGS. 15B-15D, using TeOₓ/Te as a potential replacement of Cu and As doping may reduce process steps and complexity of such devices, while maintaining the efficiency. In some embodiments, this layer may act as the necessary oxide layer to produce bifacial solar cells using CdTe-based or similar PV technologies.

The processes described herein can be performed using various methods including, but not limited to, sputtering, radio frequency (RF) sputtering, magnetron sputtering, evaporation, sublimation, co-sublimation, close-space sublimation, metal organic chemical vapor deposition (MOCVD), chemical vapor deposition, physical vapor deposition, diffusion, atomic layer deposition, molecular beam epitaxy (MBE), electroplating, dip coating, evaporation, and spin coating. In an alternative example, one or more of the above described processes can be performed by a supplier on a preceding process including, but not limited to, deposition of layers during manufacturing of glass or other substrate/superstrate.

The following example is provided to illustrate the subject matter of the present disclosure. The example is not intended to limit the scope of the present disclosure and should not be so interpreted.

### EXAMPLES

### Example 1

A CdTe solar cell can include a front interface oxide layer of Al₂O₃, the oxide layer being about 2 nanometers (nm) in thickness. A solar cell having such an oxide layer has been shown to have increased performance, stability, and manufacturability perspectives. The use of Al₂O₃ has been shown to form a double heterojunction device having a high recombination lifetime. A solar cell device as described in this example has been shown to have a lifetime of over 1.4 microseconds (μs), as compared to the 10 nanoseconds (ns) lifetime of a solar cell without the described Al₂O₃ layer. As such, it has been shown that the Al₂O₃ layer provides a resistive buffer layer which prevents charges from being collected within the solar cell.

Additionally, a solar cell device having a thin oxide layer deposited on the back-surface of the semiconducting material has also shown significant improvements in performance. In at least one example, the back-surface oxide layer can also be an Al₂O₃ layer. An exemplary diagram of a solar cell device in accordance with this disclosure is shown in FIG. 3A (indicating the presence of an oxide buffer on both the front and back surfaces of the semiconducting material).

In at least one example, a solar cell having an oxide layer of Al₂O₃ can produce improved performance qualities, when compared to a solar cell having an MgZnO oxide layer. Additionally, Al₂O₃ has been shown to provide stability over long periods of time, as well as in the presence of high operating temperatures and humidity.

### Example 2

FIG. 7B, FIG. 7C, FIG. 7D, FIG. 7E, FIG. 7F, FIG. 7G, FIG. 7H, and FIG. 7I show the results of As doping with and without heat and Cd vapor overpressure on open-circuit voltage, short-circuit voltage, fill-factor, and efficiency on the exemplary solar cell shown in FIG. 7A.

FIG. 8B, FIG. 8C, FIG. 8D, and FIG. 8E show the results of the effect of CdCl₂ treatment time on open-circuit voltage, short-circuit voltage, fill-factor, and efficiency on the exemplary solar cell shown in FIG. 8A.

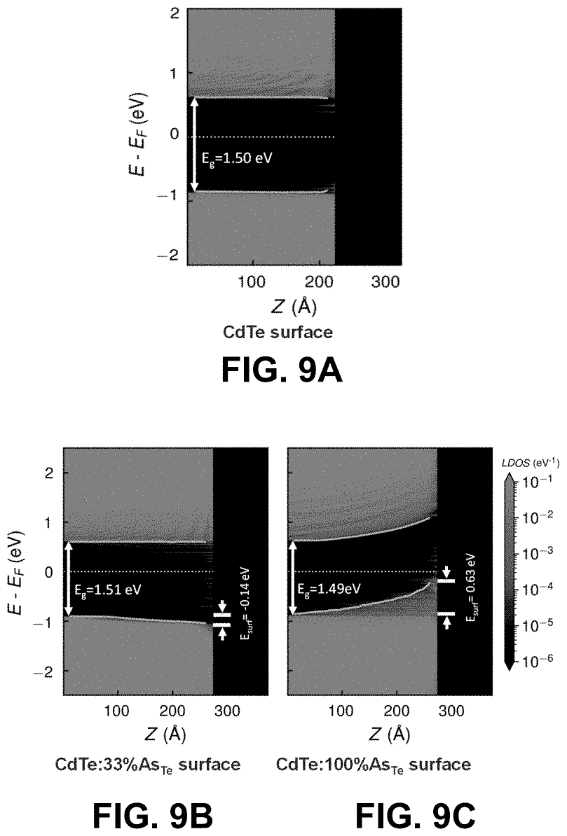

FIG. 9A, FIG. 9B, and FIG. 9C are DFT simulations showing higher doping at the back of the absorber. Monolayer As_{Te} doped CdTe surface gives favorable band alignment for hole transport.

FIG. 10B, FIG. 10C, FIG. 10D, FIG. 10E, and FIG. 10F show the results of different NiO layer thickness on open-circuit voltage, short-circuit voltage, fill-factor, efficiency, and current density on the exemplary solar cell shown in FIG. 10A. The lower thicknesses had higher efficiencies and fill-factor. The NiO layer may have a thickness of less than 20 nm, less than 5 nm, or less than 2 nm. Table 2 provides additional data on 2 nm, 5 nm, and 20 nm thickness NiO.

TABLE 2

| | V_{OC} [mV] | Fill Factor [%] | J_{SC} [mA/cm²] | Efficiency |
|---|---|---|---|---|
| 2 nm NiO | 785 | 68.4 | 27.2 | 14.57 |
| 20 nm NiO | 788 | 37.5 | 26.7 | 7.89 |
| 5 nm NiO | 785 | 68.1 | 27.2 | 14.55 |

FIG. 11B, FIG. 11C, FIG. 11D, and FIG. 11E show the results of doping with arsenic and copper on open-circuit voltage, short-circuit voltage, fill-factor, efficiency, and current density on the exemplary solar cell shown in FIG. 11A. The CdTe may be doped on the back surface of the absorber may be doped with arsenic, copper, or a combination thereof.

FIG. 12B, FIG. 12C, FIG. 12D, FIG. 12E, show the results of As doping with NiO/NiO:Cu and MZO thickness on open-circuit voltage, short-circuit voltage, fill-factor, and efficiency on the exemplary solar cell shown in FIG. 12A. FIG. 12F, FIG. 12G, FIG. 1211, and FIG. 121 show the results of the stability of arsenic with NiO:Cu over time on voltage, current density, fill-factor, and efficiency on the exemplary solar cell shown in FIG. 12A. In some examples, arsenic with NiO:Cu may be stable from at least 1 day to at least 6 days. The arsenic with NiO:Cu may be stable for more than 6 days.

FIG. 13B, FIG. 13C, FIG. 13D, and FIG. 13E show the results of SiO₂ with MZO on open-circuit voltage, short-circuit voltage, fill-factor, and efficiency on the exemplary solar cell shown in FIG. 13A. FIG. 13F shows the results of the effect of SiO₂ thickness on J-V performance on the exemplary solar cell shown in FIG. 13A. The SiO₂ layer may have a thickness of 0 nm to 5 nm. Table 3 provides additional data on 0 nm, 2 nm, and 5 nm thickness SiO₂.

TABLE 3

| | V_{OC} [mV] | Fill Factor [%] | J_{SC} [mA/cm²] | Efficiency |
|---|---|---|---|---|
| 0 nm SiO₂ | 861 | 28.7 | 60.5 | 14.94 |
| 2 nm SiO₂ | 839 | 26.4 | 72.7 | 16.10 |
| 5 nm SiO₂ | 825 | 28.5 | 74.0 | 17.37 |

FIG. 14B, FIG. 14C, FIG. 14D, FIG. 14E, FIG. 14F, and FIG. 14G show the results of using MgO for back surface passivation on open-circuit voltage, short-circuit voltage, fill-factor, efficiency, PL counts, and current density on the exemplary solar cell shown in FIG. 14A.

### Example 3

FIGS. 15B-15D show example device performances of the solar cell shown in FIG. 15A. These Figures show that contacting the Cd(Se)Te absorber with TeOx/Te yields performance equal to or better than the reference baseline. It is also shown that using TeOₓ with a Te layer at the back surface may eliminate the need for Cu, As, or any other dopant. Similar performance may also be achieved with the use of other metal, oxide, alloy, and/or doped contact layers. Optimization of TeOₓ may lead to improvement in Voc with arsenic or another group V dopant.

### Example 4

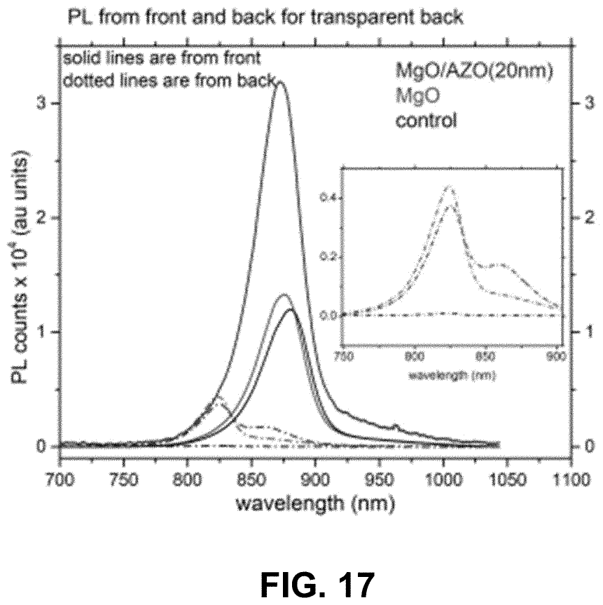

In the past, without the additional layers and processing scheme, PL intensity measured from the glass side was consistently found to be very high. However, when the same measurements were performed from the back of the deposited films, no PL response was registered. This is shown in the FIG. 17 as the control sample. When the new layers and process were added, there was a substantial improvement in PL response from the back suggesting we are able to generate charge carriers by shining light from both sides of the device and at the same time able to collect them.

The PL measurements with illumination from both ends of the devices is shown in FIG. 17. When measured with front illumination, PL signal at 870 nm or 1.4 eV (typical to a CdSeTe) was seen for all samples. The MgO and control sample had a comparable PL signal, but the signal from the sample with a bilayer of MgO/ZnO:Al was more than 2× higher. When illuminated from the back, the PL signals for the control sample was null. For the sample with MgO, a distinct peak at 830 nm (typical to the CdTe) was seen with a hint of a shoulder towards a longer wavelength. However, for the MgO/ZnO:Al two distinct peaks at 830 nm and 870 nm were seen.

The CdSeTe film was 3 μm away from the back end of the devices, therefore the 870 nm signal coming from MgO/ZnO:Al devices signifies that the Se diffuses much deeper into the CdTe after CdCl₂ and the n-type ZnO:Al bends the energy bands to amplify the signals.

The incorporation of MgO at both ends of the CdTe based absorber in two device structures were studied. PL signals from the back side illumination were detected, crucial to probe the back surface of CdTe thin films. The first structure fabricated and tested as a bifacial solar cell had the following structure: Tec10/MZO (100 nm)/CST40 (500 nm)/CdTe (3 um)/CdCl₂/MgO (2 nm)/NiO (0, 2, 5 nm)/ITO (60 nm)/CdCl₂/CuCl. The second structure fabricated and tested as a bifacial solar cell had the following structure: Glass/TCO/MZO/SiO₂/CST40/CdTe:As/MgO/NiO/CuCl/ITO/CdCl₂.

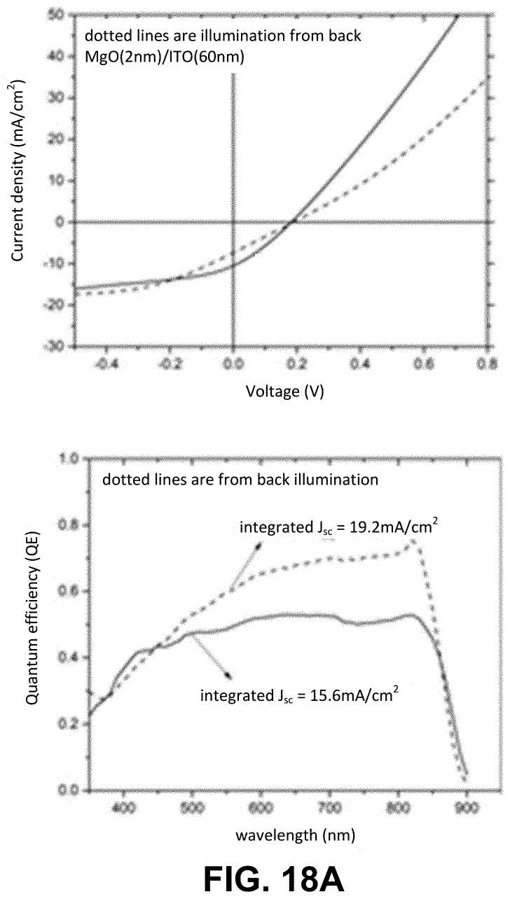

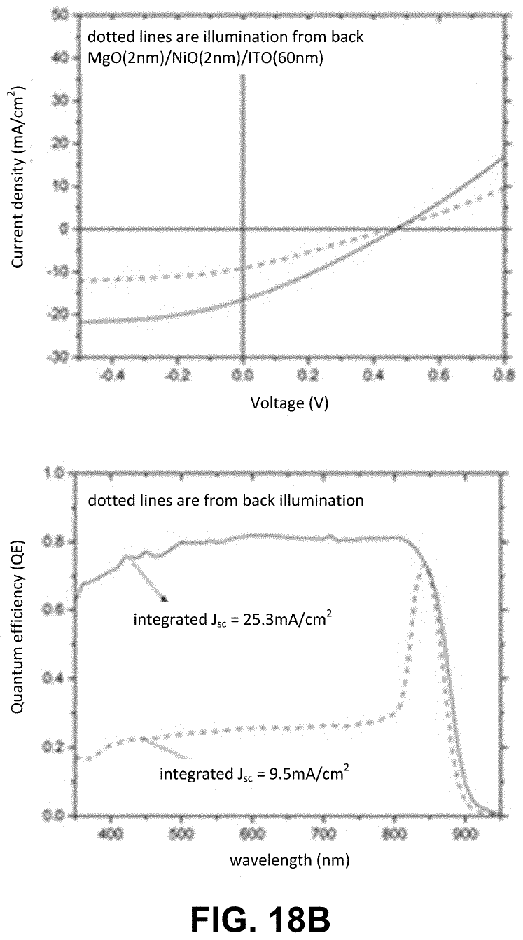

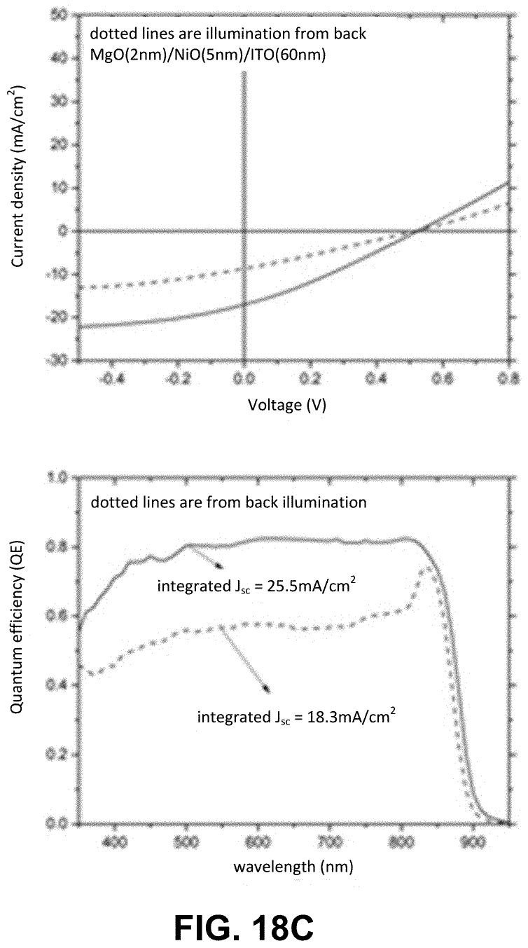

The device results shown in FIGS. 18A-18C clearly show the potential of these structure, processes, and materials for bifacial solar cell. It is envisioned that other metallic and non-metallic oxides may also be used in place of the MgZnO (MZO), MgO, and NiO with suitable band alignment. Moreover, SiO₂ may also be introduced at the front interface between MZO and CST40 which may provide improvements in the performance.

1. A thin-film solar cell with improved efficiency, the thin-film solar cell comprising:
a semiconducting/absorber layer comprising a front-surface and a back-surface;
one or more oxide layers passivated onto the front-surface of the semiconducting/absorber layer; and
one or more oxide layers passivated onto the back-surface of the semiconducting/absorber layer,
wherein the thin-film solar cell exhibits an efficiency of at least 10%.

2. The thin-film solar cell of claim 1, wherein a first layer of the one or more oxide layers on the front-surface of the semiconducting/absorber layer is formed from silicon dioxide (SiO₂), magnesium oxide (MgO), or magnesium zinc oxide (MgZnO).

3. The thin-film solar cell of claim 2, wherein the first layer on the front-surface of the semiconducting/absorber layer is less than 100 nm in thickness.

4. The thin-film solar cell of claim 2, wherein the first layer on the front-surface of the semiconducting/absorber layer is about 2 nm to 5 nm in thickness.

5. The thin-film solar cell of claim 2, wherein the first layer on the front-surface of the semiconducting/absorber layer is less than 2 nm in thickness.

6. The thin-film solar cell of claim 1, wherein the thin-film solar cell comprises at least one additional oxide layer on the front-surface of the semiconducting/absorber layer.

7. The thin-film solar cell of claim 6, wherein the at least one additional oxide layer on the front-surface is formed from a material selected from the group consisting of copper aluminum oxide (CuAlO₃), strontium copper oxide (SrCu₂O₂), copper oxide (Cu₂O), MgZnO, aluminum oxide (Al₂O₃), and tin oxide (SnO₂).

8. The thin-film solar cell of claim 1, wherein a first layer of the at least one oxide layers on the back-surface of the semiconducting/absorber layer is formed from a material selected from the group consisting of MgO, Al₂O₃, and tellurium dioxide (TeO₂).

9. The thin-film solar cell of claim 8, wherein the first layer on the back-surface of the semiconducting/absorber layer is less than 100 nm in thickness.

10. The thin-film solar cell of claim 8, wherein the first layer on the back-surface of the semiconducting/absorber layer is about 2 nm to 5 nm in thickness.

11. The thin-film solar cell of claim 8, wherein the first layer on the back-surface of the semiconducting/absorber layer is less than 2 nm in thickness.

12. The thin-film solar cell of claim 1, wherein the thin-film solar cell comprises at least one additional oxide layer on the back-surface of the semiconducting/absorber layer.

13. The thin-film solar cell of claim 12, wherein the at least one additional oxide layer on the back-surface is formed from a material selected from the group consisting of nickel oxide (NiO), copper aluminum oxide (CuAlO₃), strontium copper oxide (SrCu₂O₂), copper oxide (Cu₂O), magnesium zinc oxide (MgZnO), aluminum oxide (Al₂O₃), ZnO:Al, and tin oxide (SnO₂).

14. The thin-film solar cell of claim 13, wherein the at least one additional oxide layer on the back-surface is formed from NiO doped with copper.

15. The thin-film solar cell of claim 1, wherein the semiconducting/absorber layer is formed from a material comprising cadmium telluride (CdTe) and/or a ternary alloy of CdTe comprising CdSeTe, CdMgTe, CdZnTe or CdHgTe.

16. The thin-film solar cell of claim 15, wherein prior to passivating the at least one oxide layer onto at least one back-surface of the semiconducting/absorber layer, the at least one surface of the semiconducting/absorber layer is doped using a dopant selected from the group consisting of nitrogen, phosphorus, arsenic, antimony, and bismuth, and copper.

17. The thin-film solar cell of claim 16, wherein the semiconducting/absorber layer is doped with arsenic.

18. The thin-film solar cell of claim 14, wherein the semiconducting/absorber layer is not doped and further comprises a transparent contact deposited on the one or more oxide layers passivated onto the back-surface of the semiconducting/absorber layer.

19. The thin-film solar cell of claim 1, further comprising a telluride layer disposed on one or more oxide layers on the back-surface the semiconducting/absorber layer.

20.-38. (canceled)
